(19) United States
(12) Patent Application Publication
(10) Pub. No.: US 2013/0340829 A1
(43) Pub. Date: Dec. 26, 2013

(54) POLYMER SHEET FOR SOLAR CELL, PROCESS FOR PRODUCTION THEREOF, SOLAR CELL BACKSHEET AND SOLAR CELL MODULE

(71) Applicant: FUJIFILM Corporation, Tokyo (JP)

(72) Inventor: Akira HATAKEYAMA, Kanagawa (JP)

(73) Assignee: FUJIFILM Corporation, Tokyo (JP)

(21) Appl. No.: 14/013,899

(22) Filed: Aug. 29, 2013

Related U.S. Application Data
(63) Continuation of application No. PCT/JP2012/057390, filed on Mar. 22, 2012.

(30) Foreign Application Priority Data
Mar. 25, 2011 (JP) 2011-068658

(51) Int. Cl. H01L 31/048; H01L 31/0203

(52) U.S. Cl. CPC H01L 31/0487; H01L 31/0203
USPC 136/259; 428/447; 428/336; 427/74

(57) ABSTRACT

A polymer sheet for a solar cell, including a polyester base material having a carboxyl group content of 15 eq/t or less, a minute endothermic peak temperature Tmeta (° C.) of 220° C. or lower as determined by differential scanning calorimetry, and an average elongation retention ratio of 10% or more as determined after standing under conditions of 125° C. and 100% RH for 72 hours, a polymer layer provided on the polyester base material and including a composite polymer containing, in a molecule, 15% to 85% by mass of siloxane structural units represented by Formula (1) and 85% to 15% by mass of non-siloxane-based structural units:

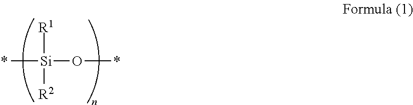

wherein, each of R¹ and R² independently represents hydrogen, halogen or a monovalent organic group; R¹ and R² may be same or different; a plurality of R¹ and R² may be same or different; and n represents an integer of 1 or more.

### CROSS-REFERENCE TO RELATED APPLICATION

This application is a continuation application of, and claims priority to, International Application No. PCT/JP/2012/057390, filed Mar. 22, 2012, which is incorporated herein by reference. Further, this application claims priority from Japanese Patent Application No. 2011-068658, filed Mar. 25, 2011, which is incorporated herein by reference.

### BACKGROUND OF THE INVENTION

1. Technical Field

The present invention relates to a polymer sheet for a solar cell, a process for production thereof, a backsheet for a solar cell, and a solar cell module.

2. Background Art

Solar cells are power generation systems which do not discharge carbon dioxide during power generation and have a low environmental load, and in recent years, solar cells have been rapidly popularized. A polymer sheet used in a solar cell is required to have various properties, such as durability coping with the usage environment of solar cells which are placed on roofs or the like and are exposed to rain, or transparency in order not to disturb the power generation efficiency of the solar cell. Further, as a polymer sheet for a solar cell, a sealing material for a solar cell (which may also be referred to as, simply, a “sealing material”) which seals a solar cell element (cell), a backsheet for a solar cell which protects the sealing material from the external environment, and the like are known.

A solar cell module generally has a structure in which photovoltaic cells are sandwiched between a front face glass on a sunlight incident side and a so-called backsheet that is placed on the opposite side (rear side) from the sunlight incident side. A space between the front face glass and the photovoltaic cells and a space between the photovoltaic cells and the backsheet are respectively sealed with an EVA (ethylene-vinylacetate) resin or the like.

The backsheet serves to prevent moisture penetration from the rear face of the solar cell module. Conventionally, glass, fluoro resin or the like was used for the backsheet, but in recent years, in consideration of cost, polyester has started to be used. The backsheet is not merely a polymer sheet, but depending on the circumstances, is provided with various functions as described below.

For example, a backsheet, which has white inorganic fine particles, such as titanium oxide, added therein so as to be provided with a function of light reflection as one of the above functions, is demanded in some cases. This is for the purpose of increasing power generation efficiency by means of returning back to the cells, by diffuse reflection, sunlight that has entered from the front face of the module and passed through the cells. Regarding this point, an example of a white polyethylene terephthalate film that includes white inorganic fine particles added therein has been disclosed (see, Japanese Patent Application Laid-Open (JP-A) Nos. 2003-060218 and 2006-210557, for example). In addition, an example of a rear face protecting sheet having a white ink layer that includes a white pigment therein has also been disclosed (see, JP-A No. 2006-210557, for example).

Further, there are cases in which the backsheet is required to have decorative properties. In this regard, in order to improve decorative properties, an example of a backsheet for a solar cell, which includes a perylene pigment, which is a black pigment, added therein, has been disclosed (see, for example, JP-A No. 2007-128943).

Furthermore, there are cases in which a polymer layer is provided as the outermost layer of a backsheet, in order to obtain strong adhesion between the backsheet and an EVA sealing material. In this regard, a technique of providing a thermally adhesive layer on a white polyethylene terephthalate film has been described (see, for example, JP-A No. 2003-060218).

In order to impart functions as described above, the backsheet has a structure in which a layer having another function is laminated on a support. An example of a means for lamination is a method of pasting sheets having various functions onto a support. For example, a method of forming a backsheet by pasting plural resin films has been disclosed (see, for example, JP-A No. 2002-100788). Further, as a method of forming a backsheet at a lower cost than the method of pasting, a method of coating layers having various functions on a support has been disclosed (see, for example, JP-A No. 2006-210557 and JP-A No. 2007-128943).

Moreover, a white polyester film for a reflective plate, in which a coated layer containing an antistatic agent and a silicone compound is provided on a white polyester film, and a backsheet for a solar cell in which an adhesion layer containing an epoxy resin, a phenol resin, a vinyl copolymer, or a siloxane compound is laminated on an organic film have been disclosed (see, for example, JP-A No. 2008-189828 and JP-A No. 2008-282873).

### SUMMARY OF INVENTION

### Technical Problem

However, although there are technologies disclosed in connection with the method of forming a backsheet by pasting, these technologies involve high cost and provide inferior interlayer adhesiveness in long-term use and insufficient durability. That is, since backsheets are directly exposed to moisture, heat, and light, the backsheets are required to have durability with respect thereto over the long-term. For example, backsheets generally have a structure adhered to an EVA sealing material, and in this case, the adhesion durability over time between the backsheet and the EVA is extremely important. Moreover, the adhesion durability between the support and the respective layers is also essential.

Methods based on coating have also been disclosed, but it is difficult to maintain adhesiveness over the long-term in an environment of relatively high temperature and humidity, or the like. These methods are not yet satisfactory in providing a polymer sheet for a solar cell, which can be produced at a low cost, and which has a good balance between functions, such as light reflectivity, and the adhesiveness to an EVA sealing material.

With regard to the polyester film or backsheet containing a silicone compound or a siloxane compound as described above, the former is inferior in the durability of a cationic polymer included as an antistatic agent, and the latter is inferior in the durability of a resin or copolymer other than the siloxane compound. Therefore, it is difficult to maintain the adhesiveness for a long time in an environment of relatively high temperature and humidity, or the like.

Further, when the durability, specifically, the durability against moisture and heat, of a base material of a polymer sheet is made high in order to impart durability to the polymer sheet, adhesiveness between the base material and a polymer layer is deteriorated. Alternatively, in order to enhance the durability of a polymer layer, a fluoro resin (which may also be referred to as a “fluorocarbon resin”) is generally used as the binder, but there has been a problem in that the polymer layer including a fluoro resin as the binder has inferior adhesion to a base board. Accordingly, the durability of a base material and the adhesiveness of a polymer layer have not been achieved at the same time.

As described above, in the current circumstances, a polymer sheet for a solar cell, such as a backsheet for a solar cell, which has both adhesiveness to an EVA sealing material that lasts for a long time and other functions (for example, reflection performance or decorativeness) in some cases, and which, at the same time, can be produced at a low cost and can exhibit sufficient durability against moisture and heat, has not yet been provided.

The present invention has been made in view of the above problems and aims to accomplish the following. Namely, an aspect of the invention is to provide a polymer sheet for a solar cell, the polymer sheet having excellent adhesion durability between respective layers and excellent adhesion durability to a constituent base material of the polymer sheet or a constituent base material of a cell-side base board (for example, a sealing material such as EVA), in a hot and humid environment, and being able to be produced at a low cost; a production method of the same; a backsheet for a solar cell; and a solar cell module which is inexpensive and has stable power generation efficiency.

### Solution to Problem

<1> A polymer sheet for a solar cell, the polymer sheet including: a polyester base material which has a carboxyl group content of 15 eq/t or less, a minute endothermic peak temperature Tmeta (° C.) of 220° C. or lower as determined by differential scanning calorimetry, and an average elongation retention ratio of 10% or more as determined after being allowed to stand under the conditions of a temperature of 125° C. and a relative humidity of 100% RH for 72 hours; and a polymer layer which is provided on the polyester base material and comprises a composite polymer which contains, in a molecule, 15% by mass to 85% by mass of siloxane structural units represented by the following Formula (1) and 85% by mass to 15% by mass of non-siloxane-based structural units:

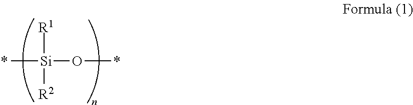

In Formula (1), each of R¹ and R² independently represents a hydrogen atom, a halogen atom or a monovalent organic group; R¹ and R² may be same or different from each other; a plurality of R¹ and R² may be same or different from each other; and n represents an integer of 1 or more.

<2> The polymer sheet for a solar cell according to the item <1>, wherein the polymer layer includes a structural unit derived from a crosslinking agent that crosslinks the composite polymer.
<3> The polymer sheet for a solar cell according to the item <1> or the item <2>, wherein the non-siloxane-based structural unit includes an acrylic structural unit.
<4> The polymer sheet for a solar cell according to the item <2> or the item <3>, wherein the crosslinking agent is at least one selected from the group consisting of a carbodiimide compound, an oxazoline compound and an epoxide-based crosslinking agent.
<5> The polymer sheet for a solar cell according to any one of the items <2> to <4>, wherein a mass ratio of a portion of the structural unit derived from the crosslinking agent is in a range of from 1% by mass to 30% by mass with respect to a mass of the composite polymer in the polymer layer.
<6> The polymer sheet for a solar cell according to any one of the items <1> to <5>, wherein the polyester base material is treated by at least one surface treatment selected from the group consisting of corona treatment, flame treatment, low-pressure plasma treatment, atmospheric pressure plasma treatment and ultraviolet ray treatment.
<7> The polymer sheet for a solar cell according to any one of the items <1> to <6>, wherein, in Formula (1), at least one of R¹ or R² represents a monovalent organic group selected from the group consisting of an alkyl group, an aryl group, an aralkyl group, an alkoxy group, an aryloxy group, a mercapto group, an amino group and an amido group.
<8> The polymer sheet for a solar cell according to any one of the items <1> to <7>, wherein a content of a carboxyl group in the polyester base material is in a range of from 1 eq/ton to 15 eq/ton.
<9> The polymer sheet for a solar cell according to any one of the items <1> to <8>, wherein the polymer sheet comprises at least two layers of the polymer layers, and a thickness of at least one layer of the polymer layers is in a range of from 0.8 μm to 12 μm.
<10> The polymer sheet for a solar cell according to any one of the items <1> to <9>, wherein the polymer sheet comprises at least two layers of the polymer layers, and at least one layer of the polymer layers is provided in contact with a surface of the polymer base material.
<11> The polymer sheet for a solar cell according to any one of the items <1> to <10>, wherein the polymer sheet comprises at least two layers of the polymer layers, and at least one layer of the polymer layers is an outermost layer provided at a furthest position from a surface of the polymer base material.
<12> The polymer sheet for a solar cell according to any one of the items <1> to <11>, wherein the polymer sheet comprises at least two layers of the polymer layers, and at least one layer of the polymer layers further includes a white pigment, and is a reflective layer having light reflective properties.
<13> The polymer sheet for a solar cell according to the item <12>, wherein the polymer sheet includes at least two layers of the polymer layers, one of the at least two layers is the reflective layer and another of the at least two layers is provided between the reflective layer and the polyester base material.
<14> The polymer sheet for a solar cell according to any one of the items <1> to <11>, further including a reflective layer that comprises a white pigment and has light reflective properties, and including at least one layer of the polymer layers between the reflective layer and the polyester base material.
<15> A method of producing a polymer sheet for a solar cell, the method including: applying, on a polyester base material, a coating liquid containing a composite polymer which contains, in a molecule, 15% by mass to 85% by mass of siloxane structural units represented by the following Formula (1) and 85% by mass to 15% by mass of non-siloxane-based structural units to form at least one polymer layer, the polyester base material having a carboxyl group content of 15 eq/t or less, a minute endothermic peak temperature Tmeta (° C.) of 220° C. or lower as determined by differential scanning calorimetry, and an average elongation retention ratio of 10% or more as determined after being allowed to stand under the conditions of a temperature of 125° C. and a relative humidity of 100% RH for 72 hours:

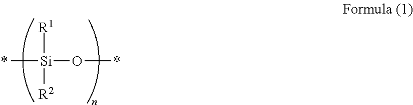

wherein, in Formula (1), each of R¹ and R² independently represents a hydrogen atom, a halogen atom or a monovalent organic group; R¹ and R² may be same or different from each other; a plurality of R¹ and R² may be same or different from each other; and n represents an integer of 1 or more.

<16> The method of producing a polymer sheet for a solar cell according to the item <15>, wherein the coating liquid further includes at least one crosslinking agent selected from the group consisting of a carbodiimide compound, an oxazoline compound and an epoxide-based crosslinking agent.
<17> The method of producing a polymer sheet for a solar cell according to the item <15> or the item <16>, wherein the coating liquid further includes a solvent, and 50% by mass or greater of the solvent is water.
<18> A backsheet for a solar cell using the polymer sheet for a solar cell according to any one of the items <1> to <14>, or a polymer sheet for a solar cell produced by the method of producing a polymer sheet for a solar cell according to any one of the items <15> to <17>, the backsheet being provided in contact with a sealing agent wherein a solar cell element is sealed by the sealing agent on a side of a base material for the solar cell element.
<19> The backsheet for a solar cell according to the item <18>, further including a readily-adhesive layer having an adhesion force of 5N/cm or greater with respect to the sealing agent on an opposite surface side of the polyester base material from a surface side at which the polymer layer is provided.
<20> The backsheet for a solar cell according to the item <18> or the item <19>, including two or more polymer sheets which are the polymer sheets for a solar cell according to any one of the items <1> to <14>, and the polymer sheet for a solar cell produced by the method of producing a polymer sheet for a solar cell according to any one of the items <15> to <17>, the two or more polymer sheets being adhered together with an adhesive agent.
<21> The backsheet for a solar cell according to any one of the items <18> to <20>, further including a barrier layer which prevents penetration of at least one of water or gas therein.
<22> A solar cell module comprising the backsheet for a solar cell according to any one of the items <18> to <21>.
<23> A solar cell module including: a transparent front base board through which sunlight enters; a cell structural portion which is provided on the front base board and comprises a solar cell element and a sealing material that seals the solar cell element; and the backsheet for a solar cell according to any one of the items <18> to <21>, the backsheet being provided on a side of the cell structural portion opposite from a side at which the front base board is placed, so as to be adjacent to the sealing material.

### Advantageous Effects of Invention

According to the present invention, a polymer sheet for a solar cell, the polymer sheet exhibiting excellent adhesion durability between respective layers and excellent adhesion durability to the constituent base material of the polymer sheet or the constituent base material of a cell-side base board (for example, a sealing material such as EVA), in a hot and humid environment, and being able to be produced at a low cost; a producing method of the same; and a backsheet for a solar cell may be provided.

Further, according to the present invention, a solar cell module which is inexpensive and has stable power generation efficiency may be provided.

### DESCRIPTION OF EMBODIMENTS

Hereinafter, a polymer sheet for a solar cell, a method for producing the same, and a solar cell module of the present invention are described in detail.

<Polymer Sheet for Solar Cell and Method for Producing the Same>

The polymer sheet for a solar cell of the present invention is a polymer sheet including a polyester base material which has a carboxyl group content of 15 eq/t or less, a minute endothermic peak temperature Tmeta (° C.) of 220° C. or lower as determined by differential scanning calorimetry, and an average elongation retention ratio of 10% or more as determined after being allowed to stand under the conditions of a temperature of 125° C. and a relative humidity of 100% RH for 72 hours; and a polymer layer which is provided on the polyester base material and contains a composite polymer which contains, in the molecule, 15% by mass to 85% by mass of siloxane structural units represented by the following Formula (1) and 85% by mass to 15% by mass of non-siloxane-based structural units.

Here, R¹ and R² each independently represent a hydrogen atom, a halogen atom, or a monovalent organic group, and R¹ and R² may be identical with or different from each other. n represents an integer of 1 or more.

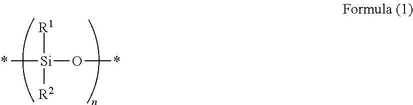

In Formula (1) above, R¹ and R² each independently represent a hydrogen atom, a halogen atom, or a monovalent organic group; and R¹ and R² may be identical with or different from each other. n represents an integer of 1 or more. Plural R¹s may be identical with or different from each other, and plural R²s may be identical with or different from each other.

In the present invention, since the polymer layer, which is a constituent layer of the polymer sheet, is constructed by using a specific composite polymer which contains, in the molecule, non-siloxane-based structural units and (poly)siloxane structural units that copolymerize with these non-siloxane-based structural units, the adhesive power between the respective layers and the adhesive power to the polyester base material or the constituent base material of a cell-side base board (for example, a sealing material such as EVA) are improved and deterioration due to heat or moisture is suppressed. Accordingly, under the environmental conditions of being exposed to heat or moisture for a long time, the adhesive strength can be maintained high over a long period of time, and long-term durability can be ensured. Thereby, when a solar cell module is constructed, satisfactory power generation performance may be obtained, and also power generation efficiency may be maintained stable for a long time.

The polymer layer in the present invention can be applied to any layer that constitutes a polymer sheet. For example, the polymer layer can be applied as a reflective layer or a back layer, which are described below, or an adhesive layer that is used to bond a functional layer such as a reflective layer to a polyester base material. Since durability in a hot and humid environment of heat, moisture, or the like is excellent, it is particularly preferable that the polymer layer, among the constituent layers of a polymer sheet, is used as a polymer layer which is disposed between a reflective layer containing a white pigment or the like and a polyester base material. Further, in the case of being prepared as a solar cell module, it is also particularly preferable that the polymer layer is used as an outermost layer that is exposed to the external environment, namely, as a back layer.

(Polyester Base Material)

The polyester base material according to the present invention has a carboxyl group content of 15 eq/t or less, a minute endothermic peak temperature Tmeta (° C.) of 220° C. or lower as determined by differential scanning calorimetry, and an average elongation retention ratio of 10% or more as determined after being allowed to stand under the conditions of a temperature of 125° C. and a relative humidity of 100% RH for 72 hours.

Since the base material has such a configuration, the base material can have high durability.

Conventionally, when such a high durable polyester base material is used, the adhesiveness between the base material and a polymer layer in a hot and humid environment is deteriorated. The mechanism of this is not clear, but it is thought as follows. Namely, in a case in which a polyester base material is used as the base material, since molecular orientation of polyester proceeds in the high durable polyester base material, the surface of the base material becomes to have a structure close to the crystal state, and thus the molecules of the base material and the molecules of the polymer layer are less likely to be mixed.

However, in the polymer sheet for a solar cell of the present invention, a polymer layer including a composite polymer which contains, in the molecule, 15% by mass to 85% by mass of siloxane structural units represented by the following Formula (1) and 85% by mass to 15% by mass of non-siloxane-based structural units is provided on a high durable polyester base material as described above. Since the polymer sheet has such a configuration, although the reason is not clear, adhesion durability in a hot and humid environment is excellent, regardless that the base material has high durability.

Hereinafter, the polyester base material according to the present invention is described in detail.

—Carboxyl Group Content (AV)—

The carboxyl group content (acid value: AV) in the polyester used in the polyester base material is 15 eq/t (ton; hereinafter, the same applies) or less, preferably 12 eq/t or less, and more preferably 8 eq/t or less.

When the carboxyl group content is 15 eq/t or less, hydrolysis resistance may be maintained, and reduction in strength when the polyester base material is subjected to wet heat aging may be suppressed low.

A carboxyl group has a function of forming a hydrogen bond with a hydroxyl group present on the surface of a member or a layer that is adjacent to the polyester base material, and thereby enhancing the adhesive force. For this reason, it is desirable that the lower limit of the carboxyl group content is 1 eq/t. Note that, in this specification, “equivalents/ton (eq/t)” represents molar equivalents per 1 ton.

H⁺ in the carboxyl group serves as an acid catalyst and has a function of hydrolyzing a polyester molecule. Therefore, with an AV exceeding 15 eq/t, in a case in which the polyester base material is subjected to aging under high humidity, the molecular weight at the surface of the polyester base material may be decreased due to hydrolysis, and the mechanical strength may be reduced. As a result, the surface of the polyester base material may be destructed and thus, peeling (adhesion failure) of the polymer layer from the polyester base material may occur.

Specific examples of a method for the adjustment of AV include adjustment of the “plane orientation coefficient” of the polyester base material, adjustment of the kinds and contents of the “constituent components” that constitute the polyester, addition of additives such as a “buffering agent” or a “terminal blocking agent”, adjustment of the “amount of phosphorous atoms” present in the polyester, and the like. In addition, it is possible to adjust the AV by selecting the type of a polymerization catalyst or the film-forming conditions (film-forming temperature or time).

Here, among the above specific methods for the adjustment, in the case of adjusting the AV to fall within the range in the present invention by the method of adjusting the amount of addition of additives, such as a “buffering agent” or a “terminal blocking agent”, and/or the “amount of phosphorous atoms”, it is necessary to further increase the contents thereof in the polyester. However, incorporation of an excess amount of additives or phosphorous atoms in polyester may bring about problems, such as precipitation of additives and the like at the surface of the base material when the base material is subjected to wet heat aging or an increase of the degree of thermal shrinkage due to excessively strong orientation, and consequently causes occurrence of adhesion failure.

—Minute Endothermic Peak Temperature Tmeta (° C.) Determined by Differential Scanning Calorimetry—

The polyester base material in the present invention has a minute endothermic peak temperature Tmeta (° C.) of 220° C. or lower, as determined by differential scanning calorimetry (hereinafter, may also be referred to as “DSC”). The minute endothermic peak temperature is more preferably from 150° C. to 215° C., and even more preferably from 160° C. to 210° C.

The minute endothermic peak temperature Tmeta (° C.) can be adjusted to fall within the temperature range according to the invention by controlling the “plane orientation coefficient” in the polyester base material and the “temperature of the heat fixing which is carried out after stretching” during the formation of the polyester base material. The temperature of the heat fixing which is carried out after stretching is preferably from 150° C. to 220° C., more preferably from 160° C. to 210° C., and even more preferably from 170° C. to 200° C.

A specific method for the measurement of Tmeta (C) is described below.

—Average Elongation Retention Ratio—

The polymer sheet of the present invention is characterized in that the backsheet has a high adhesive force even after a lapse time under moisture and heat. To achieve the above feature, it is preferable to suppress a decrease in adhesive force by suppressing hydrolysis at the surface of the polyester base material. From this point of view, the “average elongation retention ratio after being allowed to stand under the conditions of a temperature of 125° C. and a relative humidity of 100% RH for 72 hours” is adopted as a standard for the hydrolysis at the surface of a polyester base material. In the present invention, it is necessary that the average elongation retention ratio is 10% or more.

Here, the term “elongation retention ratio (Lr)” refers to the ratio (%) of the breaking elongation (Li) before a lapse time under moisture and heat, and the breaking elongation (Lt) after a lapse time under moisture and heat, and is a value determined according to the following Equation.

Lr(%)=100×(Lt)/(Li)

The “average elongation retention ratio” in the present invention is a value obtained by carrying out measurement of elongation retention ratios in the longitudinal direction (MD) of the polyester base material and in the direction orthogonal thereto (TD), and is expressed as an average value.

Examples of a method for the adjustment of elongation retention ratio include adjustment of the “plane orientation coefficient” of the polyester base material, adjustment of the “intrinsic viscosity” of the polyester, adjustment of the kinds and contents of the “constituent components” that constitute the polyester, addition of additives such as a “buffering agent” or a “terminal blocking agent”, adjustment of the “amount of phosphorous atoms” present in the polyester, and the like.

As the hydrolysis proceeds easier, the molecular weight gets lower, and therefore, the value of the average elongation retention ratio exhibited by the polyester base material decreases more easily. From this point of view, it is necessary that the polyester base material in the present invention has an average elongation retention ratio of 10% or more. The average elongation retention ratio is more preferably from 20% to 95%, and even more preferably from 30% to 90%.

By setting the average elongation retention ratio at 10% or more, peeling (adhesion failure) of the polymer sheet caused by the hydrolysis of the polyester can be effectively suppressed.

A specific method for the measurement of average elongation retention ratio is described below.

—Thermal Shrinkage Ratio and Distribution Thereof—

In one of suitable aspects of the polyester base material according to the present invention, the thermal shrinkage ratios under the conditions of 150° C. and 30 minutes in the longitudinal direction (MD) of the polyester base material and in the direction orthogonal thereto (TD) are each 1.0% or less, and the variation ratios of the thermal shrinkage are each from 10% to 20%.

The present inventors have found that there are cases in which the failure of adhesion due to wet heat aging between the polyester base material and the polymer layer is caused by the occurrence of thermal shrinkage due to residual strains in the polyester base material. That is, in a case in which thermal shrinkage occurs due to residual strains in the polyester base material that has been subjected to wet heat aging, shrinkage stress occurs between the polymer layer and the polyester base material due to the thermal shrinkage, and this shrinkage stress induces adhesion failure of the polymer layer.

The action thereof is not clear, but is thought to be as follows. Namely, when thermal shrinkage in the polyester base material is uniform in a base material plane, stress also occurs uniformly, and thus the polymer layer is easily peeled off. On the contrary, as in the case of a polyester base material according to a preferred aspect of the invention, when distribution is present in thermal shrinkage, even if sites with large thermal shrinkage are present in a base material plane, since sites with small thermal shrinkage are present in the same plane, thermal shrinkage stops at these sites (that is, shrinkage does not spread.) Thus, the shrinkage force does not reach a level that is sufficiently large to affect the entire base material, and consequently, peeling of the polymer layer is suppressed.

The variation ratio of the thermal shrinkage of the polyester base material in a suitable aspect of the invention is preferably from 1% to 20%. The variation ratio of the thermal shrinkage is more preferably from 2% to 15%, and even more preferably from 3% to 12%.

Here, the variation ratio of the thermal shrinkage of the polyester base material is obtained by carrying out measurement at five points at an interval of 10 cm in the longitudinal direction (MD) of the polyester base material and in the direction orthogonal thereto (TD), respectively, and then determining the variation ratios of the thermal shrinkage (Bts) (%) from the following Equation, and selecting the larger value.

(Bts)(%)=100×(Bmax−Bmin)/(Bav)

Here, Bts represents the variation ratio of the thermal shrinkage; Bmax represents the maximum value of thermal shrinkage; Bmin represents the minimum value of thermal shrinkage; and Bav represents the average value of thermal shrinkage.

When the variation ratio of the thermal shrinkage exceeds 20%, the dimensional variation between the sites with large thermal shrinkage and the sites with small thermal shrinkage becomes too large, a crater-shaped shrinkage portion tends to occur, and concentration of stress may occur along the rim of this crater, and thus, peeling (adhesion failure) may occur easily. Whereas, when the variation ratio of the thermal shrinkage is less than 1%, the effect of suppressing shrinkage as described above is difficult to be achieved, which is not preferable.

When the area is small, such a shrinkage stress in the polyester base material is less likely to occur. Therefore, the effect of adjusting the variation ratio of the thermal shrinkage to fall within the above range is particularly realized, when the polymer layer is pasted to a panel having a large area such as 0.5 m² or greater (more preferably 0.75 m² or greater, and even more preferably 1 m² or greater). This is because, when the area is small, the probability of coexistence of the portion with large amount of shrinkage and the portion with small amount of shrinkage is low.

Moreover, control of such thermal shrinkage ratio and variation ratio of the thermal shrinkage is particularly useful in realizing the effect on improvement of adhesion after a lapse time under moisture and heat. That is, in a case in which thermal shrinkage has occurred during wet heat aging under high humidity, and also when the humidity is high, water penetrates to the interface between the polyester base material and an adjacent member or adjacent layer that is capable of forming a hydrogen bond with the polyester base material, and cuts the hydrogen bond, and thus, adhesion is likely to be lowered. However, even under such circumstances, when the thermal shrinkage ratio and the variation ratio of the thermal shrinkage are controlled to fall within the above ranges, respectively, the shrinkage stress due to residual strains can be reduced, and thus, the adhesive force may be easily ensured.

The thermal shrinkage ratio of the polyester base material according to the invention is measured under the conditions of 150° C. and 30 minutes.

A preferred range of the thermal shrinkage ratio is, both in the longitudinal direction (MD) and a direction orthogonal thereto (TD), preferably 1% or less, more preferably from −0.5% to 0.8, and even more preferably from −0.3% to 0.6% (the symbol “−” used herein means “elongation”).

When the thermal shrinkage ratio is 1% or less, the effect of adjusting a variation ratio of the thermal shrinkage to the specific range may be effectively exhibited. If the thermal shrinkage ratio exceeds 1%, the dimensional variation of the polyester base material cannot be sufficiently suppressed, and there is a tendency that the effect of adjusting the variation ratio of the thermal shrinkage to a specific range may not be obtained. On the other hand, if elongation of the polyester base material is achieved to an excessively large extent, there is a tendency that the effect of suppressing the dimensional variation in the polyester base material due to the control of the variation ratio of the thermal shrinkage may not be obtained.

The thermal shrinkage ratio may be adjusted by performing a heat treatment after stretching during the formation of the polyester base material. The temperature of the heat treatment is preferably from 150° C. to 220° C., more preferably from 160° C. to 210° C., and even more preferably from 170° C. to 200° C., and the duration is preferably from 10 seconds to 120 seconds, more preferably from 15 seconds to 90 seconds, and even more preferably from 20 seconds to 60 seconds.

Furthermore, it is preferable to allow relaxation in at least one of the vertical direction and the horizontal direction in addition to the heat treatment after stretching, and the amount of relaxation is preferably from 0.5% to 10%, more preferably from 1.5% to 9%, and even more preferably from 3% to 8%.

The variation ratio of the thermal shrinkage may be adjusted by forming a temperature distribution during the process of producing an unstretched film (raw film) by solidifying the polyester base material on a cooling roll after the step of melt extrusion performed in the film formation. That is, when a molten body is cooled, spherulites are formed; however, if the cooling rate is varied, a distribution of these spherulites may be formed. This induces an orientation distribution during the vertical and horizontal stretching, and this is expressed as a distribution of the amount of shrinkage. The distribution of the cooling rate of such a molten body may be achieved by providing a temperature distribution to the cooling roll. Such a temperature distribution is achieved by disturbing the flow of a heat medium that is circulated in the cooling roll for temperature regulation, by providing a baffle plate. The temperature distribution is preferably from 0.2° C. to 10° C., more preferably from 0.4° C. to 5° C., and even more preferably from 0.6° C. to 3° C. This temperature distribution may be provided in any direction between the longitudinal direction and the width direction.

Along with the control of such a thermal shrinkage ratio and a variation ratio of the thermal shrinkage, as will be described below, the adhesion after a lapse of time under moisture and heat may be more effectively enhanced by incorporating a “terminal blocking agent” into the polyester, and incorporating a “trifunctional or higher-functional constituent component” as a constituent component of the polyester.

The terminal blocking agent is capable of making the terminal group bulkier by reacting with the polyester, and this serves as an obstacle decreasing the mobility of polyester molecules. In the trifunctional or higher-functional constituent component, since the molecule branches via trifunctional or higher-functional group, the mobility of polyester molecules is decreased. As such, when the mobility decreases, variation of the thermal shrinkage may be easily formed. That is, stress occurs in the sites with large thermal shrinkage and the sites with small thermal shrinkage, but the polyester molecules attempt to resolve the stress (strain due to the distribution of thermal shrinkage) by moving under the effect of this stress. At this time, when the mobility decreases as described above, resolution of such a variation of thermal shrinkage is difficult to occur, and it is easier to form the variation ratio of the thermal shrinkage distribution according to the invention.

A specific method for the measurement of thermal shrinkage ratio will be described below.

—Plane Orientation Coefficient and Distribution Thereof—

The polyester base material according to the invention preferably has a plane orientation coefficient of 0.165 or greater, more preferably from 0.168 to 0.18, and even more preferably from 0.170 to 0.175. When the plane orientation coefficient is adjusted to 0.165 or greater, the molecules may be oriented, and the formation of the “semicrystalline” portion described above may be promoted, so that hydrolysis resistance may be further enhanced.

Here, the plane orientation coefficient (fₚₒ) as used herein is measured using an Abbe refractometer and is determined by the following Equation (A).

fₚₒ=(nMD+nTD)/2−nZD (A)

In the Equation (A), nMD represents the refractive index in the longitudinal direction (MD) of the film; nTD represents the refractive index in the orthogonal direction (TD) of the film; and nZD represents the refractive index in the film thickness direction. Here, the refractive index of the film in each direction may be measured based on A method defined in JIS K7142.

The plane orientation coefficient of the polyester base material may be adjusted by increasing the stretch ratio during the film formation. Preferably, it is desirable to adjust the stretch ratio in the longitudinal direction (MD) of the film as well as the orthogonal direction (TD) of the film to 2.5 to 6.0 times. In order to adjust the plane orientation coefficient of the film to 0.165 or greater, it is preferable to adjust the stretch ratios of the MD and TD respectively to 3.0 to 5.0 times. Furthermore, the plane orientation coefficient may be enhanced by “preheating” and “multistage stretching” (will be described below) during longitudinal stretching.

Further, when the plane orientation coefficient is adjusted to 0.165 or greater, hydrolysis may be suppressed and adhesion failure due to a decrease in the molecular weight at the surface of the polyester base material can be suppressed.

Furthermore, since film-forming stability is deteriorated when the stretch ratio is increased in order to increase the plane orientation coefficient, and further, since it is possible to suppress delamination (laminar peeling) caused by excessive progress of the plane orientation and enhance the adhesive force, the upper limit of the plane orientation coefficient of the base material is preferably 0.180 or less, and more preferably 0.175 or less.

According to the invention, it is preferable to provide a distribution to the plane orientation coefficient. The distribution of the plane orientation coefficient is preferably from 1% to 20%, more preferably from 2% to 15%, and even more preferably from 3% to 12%.

The adhesive force may be further enhanced by providing a distribution to the plane orientation coefficient. That is, since the polyester base material shrinks after a lapse of time under moisture and heat, shrinkage stress occurs between the polyester base material and a sealing material such as EVA, and this causes the occurrence of adhesion failure. This thermal shrinkage stress is proportional to the elastic modulus of the polyester base material, and this is proportional to the plane orientation coefficient. Therefore, when there exists a distribution in the plane orientation coefficient of the polyester base material, a distribution also occurs in the elastic modulus, and thereby sites with high elastic modulus (rigid) and sites with low elastic modulus (soft) are formed. The sites with low elastic modulus have a function of absorbing the thermal shrinkage stress that has occurred, and these sites serve as buffer areas and exhibit an effect of suppressing the decrease in adhesion. When the distribution of the plane orientation coefficient is less than 1%, there is a tendency that adhesion force thereof becomes weak due to that the thermal shrinkage stress may not be alleviated. On the other hand, when the distribution of the plane orientation coefficient is more than 20%, there is a tendency that adhesion failure is likely to occur since the thermal shrinkage stress may be highly concentrated to a portion where a degree of plane orientation is slight.

The distribution of the plane orientation coefficient in the polyester base material may be formed by adjusting the preheating temperature distribution in the vertical stretching during the formation of the polyester base material. That is, by having a preheating temperature distribution, an orientation distribution in the vertical stretching, and a crystal distribution accompanied therewith are formed, and thereby an orientation distribution in the lateral stretching is formed. The temperature distribution as used herein refers to the temperature distribution in the width direction. That is, the temperature distribution formed in the width direction causes the occurrence of a crystal distribution and an orientation distribution in the width direction after vertical stretching. These distributions form orientation unevenness across the entire surface of the film when the polyester film is stretched in the horizontal direction, and thereby a distribution in the plane orientation coefficient is formed.

The distribution of preheating temperature may be adjusted by providing a temperature distribution to the preheating roll. Specifically, it is desirable to adjust the preheating temperature distribution by disturbing the flow of a heat medium that is circulated in the preheating roll for temperature regulation, by providing a baffle plate. The temperature distribution of the preheating temperature is preferably from 0.2° C. to 10° C., more preferably from 0.4° C. to 5° C., and even more preferably from 0.6° C. to 3° C.

Along with the control of such a distribution of the plane orientation coefficient, as is described below, the adhesion after a lapse time under moisture and heat may be more effectively enhanced by incorporating a “terminal blocking agent” into the polyester, and incorporating a “trifunctional or higher-functional constituent component” as a constituent component of the polyester.

The terminal blocking agent is capable of making the terminal bulkier by reacting with the polyester, and this serves as an obstacle decreasing the mobility of the polyester molecules. In the trifunctional or higher-functional constituent component (C), since the molecule branches via trifunctional or higher-functional group, the mobility of the polyester molecules is decreased. As such, when the mobility decreases, the plane orientation distribution may be easily formed. That is, stress difference occurs between the sites with large plane orientation and the sites with small plane orientation, but the molecules attempt to resolve the stress difference by fluidizing (creeping) under the effect of the stress difference. In this process, when the mobility of the molecules decreases as described above, resolution of such plane orientation distribution is difficult to occur, and it is easier to form the distribution of the plane orientation coefficient.

A specific method for the measurement of plane orientation coefficient is described below.

—Intrinsic Viscosity (IV)—

The polyester in the polyester base material in the present invention preferably has an intrinsic viscosity (hereinafter, appropriately referred to as “IV”) in a range of from 0.6 dL/g to 1.2 dL/g. The intrinsic viscosity is more preferably from 0.65 dL/g to 1.0 dL/g, and even more preferably from 0.70 dL/g to 0.95 dL/g.

When the intrinsic viscosity of the polyester in the polyester base material is less than 0.6 dL/g, the molecules have high mobility, and there is a tendency that the distribution of the thermal shrinkage or the plane orientation as described above is easily alleviated (resolved). When the intrinsic viscosity exceeds 1.2 dL/g, shear heat generation is likely to occur during melt extrusion, and this accelerates thermal decomposition of the polyester resin and, as a result, the amount of carboxylic acid (AV) in the polyester is likely to increase. This accelerates the hydrolysis of the polyester during wet heat aging, and there is a tendency that adhesion failure is likely to occur.

The IV of the polyester in the polyester base material can be adjusted by adjusting the temperature and reaction time in the solid phase polymerization. In a suitable aspect of the solid phase polymerization, polyester pellets are heat treated in a nitrogen gas stream or in a vacuum, under the temperature condition of from 180° C. to 250° C., more preferably from 190° C. to 240° C., and even more preferably from 195° C. to 230° C., for a period of from 5 hours to 50 hours, more preferably from 10 hours to 40 hours, and even more preferably from 15 hours to 30 hours. The solid phase polymerization may be carried out at a constant temperature, or may be carried out while varying the temperature.

Further, with regard to the polyester raw material (pellets), which is supplied for the formation of the polyester base material, it is preferable that the intrinsic viscosity is in a range of from 0.6 dL/g to 1.2 dL/g, in order to satisfy the hydrolysis resistance. The intrinsic viscosity is more preferably from 0.65 dL/g to 1.0 dL/g, and even more preferably from 0.70 dL/g to 0.95 dL/g. In order to enhance the hydrolysis resistance, it is preferable to increase the intrinsic viscosity. However, in a case in which the intrinsic viscosity exceeds 1.2 dL/g, it is needed to lengthen the time for solid phase polymerization during the production of the polyester resin, and the cost is remarkably increased, which is thus not preferable. Further, in a case in which the intrinsic viscosity is less than 0.6 dL/g, since the polymerization degree is low, heat resistance and hydrolysis resistance are remarkably deteriorated, which is thus not preferable. The intrinsic viscosity of the pellets can be adjusted to fall within the above preferable range, by adjusting the polymerization conditions and solid phase polymerization conditions at the time of producing the polyester resin.

The polyester used for the polyester base material is not particularly limited as far as the polyester base material has the physical properties described above and is, for example, a linear saturated polyester which is synthesized by using an aromatic dibasic acid or an ester-forming derivative thereof and a diol or an ester-forming derivative thereof. Specific examples of such a polyester may include polyethylene terephthalate, polyethylene isophthalate, polybutylene terephthalate, poly(1,4-cyclohexylenedimethylene terephthalate), polyethylene-2,6-naphthalate, and the like. Among them, polyethylene terephthalate or polyethylene-2,6-naphthalate is particularly preferable from the viewpoint of the balance of mechanical properties and cost.

The polyester may be a homopolymer or may be a copolymer. Further, the polyester may be mixed with a small amount of another kind of resin, for example, polyimide or the like.

During the polymerization of the polyester in the present invention, it is preferable to use an Sb-based compound, a Ge-based compound, or a Ti-based compound as a catalyst, from the viewpoint of suppressing the carboxyl group content (the content of carboxyl groups) in the polyester after polymerization to a value equal to or less than a value within a predetermined range. Among them, a Ti-based compound is particularly preferable. In the case of using a Ti-based compound, it is preferable to perform polymerization by using the Ti-based compound as a catalyst in an amount of from 1 ppm to 30 ppm, more preferably from 3 ppm to 15 ppm, in terms of Ti element content in the polyester after polymerization. When the amount of the Ti-based compound used is within the above range in terms of Ti element content, it is possible to adjust the content of carboxyl groups in the polyester after polymerization to fall within the range described below, and the hydrolysis of the polyester base material can be maintained low.

Polyester synthesis using the titanium-based compound may be performed by applying a method described in Japanese published examined application patent No. 8-301,198, Japanese patent Nos. 2,543,624, 3,335,683, 3,717,380, 3,897,756, 3,962,226, 3,979,866, 3,996,871, 4,000,867, 4,053,837, 4,127,119, 4,134,710, 4,159,154, 4,269,704, 4,313,538, and the like.

The polyester according to the invention is preferably subjected to solid phase polymerization after being polymerized. Thereby, a satisfactory carboxyl group content can be achieved. The solid phase polymerization may be a continuous method (a method of filling a resin in a tower, and while heating, the resin is allowed to flow slowly for a predetermined time, and then discharging the resin) or may be a batch method (a method of supplying a resin in a container and heating the resin for a predetermined time). Specifically, the methods described in Japanese Patent Nos. 2621563, 3121876, 3136774, 3603585, 3616522, 3617340, 3680523, 3717392, 4167159, and the like can be applied to the solid phase polymerization.

The temperature of the solid phase polymerization is preferably from 170° C. to 240° C., more preferably from 180° C. to 230° C., and even more preferably from 190° C. to 220° C. Further, the time for the solid phase polymerization is preferably from 5 hours to 100 hours, more preferably from 10 hours to 75 hours, and even more preferably from 15 hours to 50 hours. The solid phase polymerization is preferably carried out in a vacuum or under a nitrogen atmosphere.

One suitable aspect of the polyester according to the invention includes a polyester having a dicarboxylic acid constituent component, a diol constituent component, and a constituent component (p) of which the sum of the number of carboxyl groups (a) and the number of hydroxyl groups (b) (a+b) is 3 or greater, the polyester having a content of the constituent component (p) of from 0.005% by mole to 2.5% by mole relative to the total amount of the constituent components contained in the polyester.

—Constituent Component (p)—

The constituent component (p) of which the sum of the number of carboxyl groups (a) and the number of hydroxyl groups (b) (a+b) is 3 or greater, will be explained.

Examples of the constituent component (p) include a carboxylic acid constituent component having a number of carboxyl groups (a) of 3 or greater, a constituent component having a number of hydroxyl groups (b) of 3 or greater, and a constituent component which is an oxyacid having both hydroxyl groups and carboxyl groups in one molecule, and has a sum of the number of carboxyl groups (a) and the number of hydroxyl groups (b) (a+b) of 3 or greater.

Examples of the carboxylic acid constituent component having a number of carboxyl groups (a) of 3 or greater include, as trifunctional aromatic carboxylic acid constituent components, trimesic acid, trimellitic acid, aphthalenetricarboxylic acid, and anthracenetricarboxylic acid; as trifunctional aliphatic carboxylic acid constituent components, methanetricarboxylic acid, ethanetricarboxylic acid, propanetricarboxylic acid, and butanetricarboxylic acid; as tetrafunctional aromatic carboxylic acid constituent components, benzenetetracarboxylic acid, pyromellitic acid, benzophenonetetracarboxylic acid, naphthalenetetracarboxylic acid, anthracenetetracarboxylic acid, and perylenetetracarboxylic acid; as tetrafunctional aliphatic carboxylic acid constituent components, ethanetetracarboxylic acid, ethylenetetracarboxylic acid, butanetetracarboxylic acid, cyclopentanetetracarboxylic acid, cyclohexanetetracarboxylic acid, and adamantanetetracarboxylic acid; as pentafunctional or higher-functional aromatic carboxylic acid constituent components, benzenepentacarboxylic acid, benzenehexacarboxylic acid, naphthalenepentacarboxylic acid, naphthalenehexacarboxylic acid, naphthaleneheptacarboxylic acid, naphthaleneoctacarboxylic acid anthracenepentacarboxylic acid, anthracenehexacarboxylic acid, anthraceneheptacarboxylic acid, and anthraceneoctacarboxylic acid; as pentafunctional or higher-functional aliphatic carboxylic acid constituent components, ethanepentacarboxylic acid, ethanehexacarboxylic acid, butanepentacarboxylic acid, butaneheptacarboxylic acid, cyclopentanepentacarboxylic acid, cyclohexanepentacarboxylic acid, cyclohexanehexacarboxylic acid, adamantanepentacarboxylic acid, and adamantanehexacarboxylic acid; and ester derivatives and acid anhydrides thereof. However, the examples are not limited to these.

Furthermore, compounds obtained by adding 1-lactide, d-lactide, an oxyacid such as hydroxybenzoic acid, and a derivative thereof, or a plural number of such oxyacids connected in series, to the carboxy terminal of the carboxylic acid constituent component, are also suitably used.

Furthermore, these may be used singly, or if necessary, plural kinds may also be used.

Examples of the constituent component having a number of hydroxyl groups (b) of 3 or greater that may be used with preference include, as trifunctional aromatic constituent components, trihydroxybenzene, trihydroxynaphthalene, trihydroxyanthracene, trihydroxycalchone, trihydroxyflavone, and trihydroxycoumarin; as trifunctional aliphatic alcohol constituent components, glycerin, trimethylolpropane, and propanetriol; as tetrafunctional aliphatic alcohol constituent components, compounds such as pentaerythritol; and constituent components (p) having a diol added to the hydroxy terminal of the compounds described above. These may be used singly, or if necessary, plural kinds may also be used.

Among the oxyacids having both hydroxyl groups and carboxyl groups in one molecule, examples of the constituent component of which the sum of the number of carboxyl groups (a) and the number of hydroxyl groups (b) (a+b) is 3 or greater include hydroxyisophthalic acid, hydroxyterephthalic acid, dihydroxyterephthalic acid, and dihydroxyterephthalic acid.

Furthermore, compounds obtained by adding 1-lactide, d-lactide, an oxyacid such as hydroxybenzoic acid, and a derivative thereof, or a plural number of such oxyacids connected in series, to the carboxy terminal of the constituent component, are also suitably used.

Furthermore, these may be used singly, or if necessary, plural kinds may also be used.

In the case where the polyester contains a constituent component (p), the content of the constituent component (p) is preferably from 0.005% by mole to 2.5% by mole relative to the total amount of the constituent components of the polyester. The content of the constituent component (p) is more preferably from 0.020% by mole to 1% by mole, even more preferably from 0.025% by mole to 1% by mole, still more preferably from 0.035% by mole to 0.5% by mole, still more preferably from 0.05% by mole to 0.5% by mole, and particularly preferably from 0.1% by mole to 0.25% by mole.

When the content of the constituent component (p) in the polyester is 0.005% by mole or less relative to the total amount of the constituent components in the polyester, there are occasions in which the effect of enhancing moisture and heat resistance is not verified. When the content is greater than 2.5% by mole, it is difficult to realize the polyester for the reason such as gelling of the resin and difficulty in melt extrusion, and even if realization of the polymer is possible, the gel is present as a foreign substance, so that there are occasions in which biaxial stretchability is decreased when the polyester is formed into a film, or a film obtained by stretching the polyester has many foreign substance defects.

When the content of the constituent component (p) in the polyester is adjusted to the range of from 0.005% by mole to 2.5% by mole relative to the total amount of the constituent components of the polyester, moisture and heat resistance may be increased while melt extrudability is maintained. Furthermore, the stretchability at the time of biaxial stretching, or the quality of the film thus obtained may be maintained.

The constituent component (p) is preferably such that the compound that has a number of carboxyl groups (a) of 3 or greater and has carboxylic acids, is an aromatic compound, or the compound that has a number of hydroxyl groups (b) of 3 or greater and has hydroxyl groups, is an aliphatic compound. A crosslinked structure may be formed without deteriorating the orientation characteristics of the polyester film, and molecular mobility may be further decreased, while moisture and heat resistance may be further increased.

In the case where the polyester contains the constituent component (p), it is also preferable to add a buffering agent or a terminal blocking agent, which will be described below, at the time of molding.

The polyester containing the constituent component (p) is preferably a highly crystalline resin, and specifically, the polyester is preferably a polyester of which the heat of crystal melting ΔHm determined from the peak area of the melting peak in a 2^{nd} run differential scanning calorimetric chart, which is obtained according to JIS K7122 (1999) by heating the resin at a temperature increase rate of 20° C./min from 25° C. to 300° C. (1^{st} run), maintaining the resin in that state for 5 minutes, subsequently rapidly cooling the resin to a temperature of 25° C. or lower, and raising the temperature again at a temperature increase rate of 20° C./min from room temperature to 300° C., is 15 J/g or greater. Preferably, it is desirable to use a resin having a heat of crystal melting of 20 J/g or greater, more preferably 25 J/g or greater, and even more preferably 30 J/g or greater. When the polyester is made highly crystalline as such, oriented crystallization may be achieved by stretching and heat treatment, and as a result, a polyester base material having excellent mechanical strength and moisture and heat resistance may be obtained.

The melting point Tm of the polyester containing the constituent component (p) is preferably 245° C. to 290° C. The melting point Tm used herein is a melting point Tm obtainable by DSC during a process of temperature increase (temperature increase rate: 20° C./min), and the temperature of a peak top that may be designated as a peak of crystal melting of a 2^{nd} run, which is obtainable by a method based on JIS K-7121 (1999) as described above, by heating the resin at a temperature increase rate of 20° C./min from 25° C. to 300° C. (1^{st} run), maintaining the resin in that state for 5 minutes, subsequently rapidly cooling the resin to a temperature of 25° C. or lower, and raising the temperature again at a temperature increase rate of 20° C./min from room temperature to 300° C., is designated as the melting point Tm1 of the polyester. More preferably, the melting point Tm is 247° C. to 275° C., and even more preferably 250° C. to 265° C. If the melting point Tm is lower than 245° C., the film has inferior heat resistance or the like, which is not preferable. Furthermore, if the melting point Tm is higher than 290° C., it may become difficult to perform extrusion processing, and therefore, it is not preferable. When the melting point Tm of the polyester is adjusted to 245° C. to 290° C., a polyester base material which achieves a good balance between heat resistance and processability may be obtained.

<Buffering Agent>

The polyester base material according to the invention preferably contains a buffering agent. Incorporation of a buffering agent is particularly preferable when the polyester contains the constituent component (p) as a constituent component thereof.

The buffering agent is preferably an alkali metal salt from the viewpoints of polymerization reactivity and moisture and heat resistance, and specific examples of the buffering agent include alkali metal salts with compounds such as phthalic acid, citric acid, carbonic acid, lactic acid, tartaric acid, phosphoric acid, phosphorous acid, hypophosphorous acid, and polyacrylic acid. Among these, it is preferable that the alkali metal element be potassium or sodium, from the viewpoint that precipitates based on catalyst residues are not easily produced. Specific examples of the buffering agent include potassium hydrogen phthalate, sodium dihydrogen citrate, disodium hydrogen citrate, potassium dihydrogen citrate, dipotassium hydrogen citrate, sodium carbonate, sodium tartrate, potassium tartrate, sodium lactate, potassium lactate, sodium hydrogen carbonate, disodium hydrogen phosphate, dipotassium hydrogen phosphate, potassium dihydrogen phosphate, sodium dihydrogen phosphate, sodium hydrogen phosphite, potassium hydrogen phosphite, sodium hypophosphite, potassium hypophosphite, and sodium polyacrylate.

Furthermore, the buffering agent is preferably an alkali metal salt represented by the following formula (I), from the viewpoints of the polymerization reactivity of the polyester, and heat resistance at the time of melt molding. Furthermore, an alkali metal is preferably sodium and/or potassium, from the viewpoints of polymerization reactivity, heat resistance, and moisture and heat resistance, and is particularly preferably a metal salt of phosphoric acid and sodium and/or potassium, from the viewpoints of polymerization reactivity and moisture and heat resistance.

POₓH_{y}M_{z} (I)

wherein x represents an integer from 2 to 4; y represents 1 or 2; z represents 11 or 2; and M is an alkali metal).

The content of the buffering agent is preferably from 0.1 mol/ton to 5.0 mol/ton, relative to the total mass of the polyester, and is more preferably from 0.3 mol/ton to 3.0 mol/ton. When the content of the buffering agent is in the range described above, moisture and heat resistance or mechanical characteristics may be further enhanced.

In the case of using an alkali metal salt represented by the formula (I) as the buffering agent, it is preferable to use phosphoric acid together. Thereby, the effect of suppressing hydrolysis by the buffering agent may be further increased, and the moisture and heat resistance of the polyester base material thus obtainable may be further increased.

In that case, it is preferable to adjust the alkali metal element content W1 in the polyester base material to the range of from 2.5 ppm to 125 ppm, and to adjust the ratio of the alkali metal element content W1 and the phosphorus element content W2, W1/W2, to the range of from 0.01 to 1. When the contents are adjusted to these ranges, the effect of suppressing hydrolysis may be further enhanced. More preferably, the alkali metal element W1 is from 15 ppm to 75 ppm, and the ratio of the alkali metal element content W1 and the phosphorus element content W2, W1/W2, is from 0.1 to 0.5. If the alkali metal element content W1 is less than 2.5 ppm, the effect of suppressing hydrolysis is insufficient, and the resulting polyester base material may not obtain sufficient moisture and heat resistance. Furthermore, if the alkali metal element content is greater than 125 ppm, the alkali metal which is present in excess may accelerate a thermal decomposition reaction at the time of melt extrusion, and the molecular weight may decrease, thereby causing a decrease in moisture and heat resistance or in the mechanical properties. Furthermore, when the ratio of the alkali metal element content W1 and the phosphorus element content W2, W1/W2, is less than 0.1, the effect of suppressing hydrolysis is insufficient. When the ratio is greater than 125 ppm, the excess phosphoric acid reacts with the polyester during the polymerization reaction to form a phosphoric acid ester skeleton into a molecular chain, and this part accelerates the hydrolysis reaction, so that hydrolysis resistance may decrease.

When the alkali metal element W1 in the polyester base material is from 15 ppm to 75 ppm, and the ratio of the alkali metal element contents W1 and W2, W1/W2, is from 0.1 to 0.5, the effect of suppressing hydrolysis resistance may be further increased, and as a result, high moisture and heat resistance may be obtained.

The buffering agent may be added during the polymerization of polyester, or may be added at the time of melt molding, but from the viewpoint of uniform dispersion of the buffering agent in the polyester, it is preferable to add the buffering agent during the polymerization. When the buffering agent is added during the polymerization, the timing of addition is such that the buffering agent may be added at any time between the completion of the esterification reaction or transesterification reaction during the polymerization of the polyester, and the early stage of the polycondensation reaction (when the intrinsic viscosity is less than 0.3). The method for addition of the buffering agent may be any of a method of directly adding a powder, and a method of preparing a solution in which the buffering agent is dissolved in a diol constituent component such as ethylene glycol and adding the solution; however, it is preferable to add the buffering agent as a solution in which the buffering agent is dissolved in a diol constituent component such as ethylene glycol. In that case, in regard to the solution concentration, if the solution is diluted to 10% by mass or less and added, it is preferable from the viewpoints that there occurs less adhesion of the buffering agent to the vicinity of the addition port, the error in the amount of addition is small, and the reactivity is satisfactory.

Furthermore, in the case of a polyester containing the constituent component (p), it is preferable that the content of diethylene glycol, which is a side product produced during the polymerization, be less than 2.0% by mass, and more preferably less than 1.0% by mass, from the viewpoints of heat resistance and moisture and heat resistance.

<Terminal Blocking Agent>

According to one preferred aspect, the polyester base material in the invention contains a terminal blocking agent. The terminal blocking agent is an additive that reacts with the terminal carboxyl group of the polyester and thereby reducing the amount of carboxyl terminals of the polyester.

Examples of the terminal blocking agent include carbodiimide compounds, epoxy compounds, and oxazoline compounds.

The terminal blocking agent is more effective when added together with the polyester during the formation of a polyester film. It is also acceptable to use the terminal blocking agent at the time of solid phase polymerization.

The terminal blocking agent may also be used together with the polyester containing the constituent component (p) of which the sum of the number of carboxyl groups (a) and the number of hydroxyl groups (b) (a+b) is 3 or greater.

The content of the terminal blocking agent in the polyester base material is preferably 0.1% by mass to 5% by mass. If the content of the terminal blocking agent is less than 0.1% by mass, the effect of blocking the carboxyl group is small, and the hydrolysis resistance may be deteriorated. Furthermore, if the content of the terminal blocking agent is larger than 5% by mass, foreign materials may be produced to a large extent during film formation, a decomposition gas may be generated, or the productivity may be affected. A more preferred upper limit of the content of the terminal blocking agent is 4% by mass, and an even more preferred upper limit thereof is 2% by mass. A more preferred lower limit of the content of the terminal blocking agent is 0.3% by mass, and an even more preferred lower limit thereof is 0.5% by mass. A more preferred range of the content of the terminal blocking agent is 0.3% by mass to 4% by mass, and an even more preferred range is 0.5% by mass to 2% by mass.

—Carbodiimide Compound—

The carbodiimide compounds are classified into monofunctional carbodiimides and polyfunctional carbodiimides.

Examples of the monofunctional carbodiimides include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, and di-β-naphthylcarbodiimide. Particularly preferred examples include dicyclohexylcarbodiimide and diisopropylcarbodiimide.

Furthermore, carbodiimides having a degree of polymerization of 3 to 15 are preferably used as the polyfunctional carbodiimides. The polyfunctional carbodiimide generally includes a repeating unit represented by the following formula —R—N═C═N— and the like. Here, R represents a divalent linking group such as alkylene group, arylene group and the like. As the repeating unit, specific examples include 1,5-naphthalenecarbodiimide, 4,4′-diphenylmethanecarbodiimide, 4,4′-diphenyldimethylmethanecarbodiimide, 1,3-phenylenecarbodiimide, 1,4-phenylene carbodiimide, 2,4-tolylenecarbodiimide, 2,6-tolylenecarbodiimide, a mixture of 2,4-tolylenecarbodiimide and 2,6-tolylenecarbodiimide, hexamethylenecarbodiimide, cyclohexane-1,4-carbodiimide, xylylenecarbodiimide, isophoronecarbodiimide, isophoronecarbodiimide, dicyclohexylmethane-4,4′-carbodiimide, methylcyclohexanecarbodiimide, tetramethylxylylenecarbodiimide, 2,6-diisopropylphenylcarbodiimide, and 1,3,5-triisopropylbenzene-2,4-carbodiimide.

These may be used singly or in combination of two or more kinds thereof.

Since the carbodiimide compounds generate isocyanate-based gases as a result of thermal decomposition, carbodiimide compounds having high heat resistance are preferred. In order to increase heat resistance, carbodiimide compounds having a higher molecular weight (degree of polymerization) are preferred, and it is more preferable to impart a structure having high heat resistance to the terminals of the carbodiimide compound. Furthermore, if a carbodiimide compound once undergoes thermal decomposition, the carbodiimide compound is prone to undergo another thermal decomposition. Therefore, it is needed to devise a process in a way such as lowering the extrusion temperature of the polyester as much as possible.

—Epoxy Compounds—

Preferred examples of the epoxy compounds include glycidyl ester compounds and glycidyl ether compounds.

Specific examples of the glycidyl ester compounds include benzoic acid glycidyl ester, t-butylbenzoic acid glycidyl ester, p-toluic acid glycidyl ester, cyclohexanecarboxylic acid glycidyl ester, pelargonic acid glycidyl ester, stearic acid glycidyl ester, lauric acid glycidyl ester, palmitic acid glycidyl ester, behenic acid glycidyl ester, versatic acid glycidyl ester, oleic acid glycidyl ester, linolic acid glycidyl ester, linoleic acid glycidyl ester, behenolic acid glycidyl ester, stearolic acid glycidyl ester, terephthalic acid diglycidyl ester, isophthalic acid diglycidyl ester, phthalic acid diglycidyl ester, naphthalenedicarboxylic acid diglycidyl ester, methylterephthalic acid diglycidyl ester, hexahydrophthalic acid diglycidyl ester, tetrahydrophthalic acid diglycidyl ester, cyclohexanedicarboxylic acid diglycidyl ester, adipic acid diglycidyl ester, succinic acid diglycidyl ester, sebacic acid diglycidyl ester, dodecanedioic acid diglycidyl ester, octadecanedicarboxylic acid diglycidyl ester, trimellitic acid triglycidyl ester, and pyromellitic acid tetraglycidyl ester. These may be used singly or in combination of two or more kinds thereof.

Specific examples of the glycidyl ether compounds include phenyl glycidyl ether, O-phenyl glycidyl ether, 1,4-bis(β,γ-epoxypropoxy)butane, 1,6-bis(β,γ-epoxypropoxy)hexane, 1,4-bis(β,γ-epoxypropoxy)benzene, 1-(β,γ-epoxypropoxy)-2-ethoxyethane, 1-(β,γ-epoxypropoxy)-2-benzyloxyethane, 2,2-bis[p-(β,γ-epoxypropoxy)phenyl]propane, 2,2-bis(4-hydroxyphenyl)propane, and a bisglycidyl polyether which is obtainable by a reaction between bisphenol such as 2,2-bis(4-hydroxyphenyl)methane and epichlorohydrin. These may be used singly or in combination of two or more kinds thereof.

—Oxazoline Compounds—

The oxazoline compounds are preferably bisoxazoline compounds, and specific examples include 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline), 2,2′-bis(4-cyclohexyl-2-oxazoline), 2,2′-bis(4-benzyl-2-oxazoline), 2,2′-p-phenylenebis(2-oxazoline), 2,2′-m-phenylenebis(2-oxazoline), 2,2′-o-phenylenebis(2-oxazoline), 2,2′-p-phenylenebis(4-methyl-2-oxazoline), 2,2′-p-phenylenebis(4,4-dimethyl-2-oxazoline), 2,2′-m-phenylenebis(4-methyl-2-oxazoline), 2,2′-m-phenylenebis(4,4-dimethyl-2-oxazoline), 2,2′-ethylenebis(2-oxazoline), 2,2′-tetramethylenebis(2-oxazoline), 2,2′-hexamethylenebis(2-oxazoline), 2,2′-octamethylenebis(2-oxazoline), 2,2′-decamethylenebis(2-oxazoline), 2,2′-ethylenebis(4-methyl-2-oxazoline), 2,2′-tetarmethylenebis(4,4-dimethyl-2-oxazoline), 2,2′-9,9′-diphenoxyethanebis(2-oxazoline), 2,2′-cyclohexylenebis(2-oxazoline) and 2,2′-diphenylenebis(2-oxazoline). Among these, 2,2′-bis(2-oxazoline) is most preferably used from the viewpoint of the reactivity with the polyester.

The bisoxazoline compounds may be used singly or in a combination two or more kinds thereof.

<Phosphorus Compound>

For the polyester film in the invention, it is also preferable to incorporate a phosphorus compound from the viewpoint of suppressing the decomposition of hydrolysis.

In the case of incorporating a phosphorus compound, it is preferable that the amount of phosphorus atoms determined by a fluorescent X-ray analysis of the polyester base material be 200 ppm or greater. The amount of phosphorus atoms is more preferably 300 ppm or greater, and even more preferably 400 ppm or greater.

As the phosphorus compound, it is preferable to use one or more phosphorus compounds selected from the group consisting of phosphoric acid, phosphorous acid, phosphonic acid, and methyl esters, ethyl esters, phenyl esters, and half esters of those acids, and other derivatives thereof. According to the invention, methyl esters, ethyl ester and phenyl esters of phosphoric acid, phosphorous acid and phosphonic acid are particularly preferred. Furthermore, as a method of incorporating the phosphorus compound, it is preferable to add the phosphorus compound when polyester raw material chips are produced.

<Other Additives>

Since the polyester base material in the invention is a constituent element of a polymer sheet, it is preferable that the polyester base material is not easily affected by deterioration due to sunlight. For that reason, a UV (ultraviolet) absorber or a substance having a characteristic of reflecting UV may be added into the polyester. Furthermore, according to one preferred aspect, the average reflectance for a radiation having a wavelength of 400 nm to 700 nm at least one surface of the base material is adjusted to 80% or greater. The average reflectance is more preferably 85% or greater, and particularly preferably 90% or greater. When the average reflectance of a radiation having a wavelength of 400 nm to 700 nm is adjusted to 80% or greater, even if a solar cell using the polymer sheet of the invention is used at places which are directly exposed to sunlight, deterioration of the polymer sheet occurs to a lesser extent.

(Method for Producing Polyester Base Material)

Next, the method for producing the polyester base material in the invention will be explained by way of an example of a biaxially oriented polyester film which uses polyethylene terephthalate (PET) as the polyester, as a representative example.

Of course, the invention is not intended to be limited to the biaxially oriented polyester film which uses a PET film, and films which use any other polymers are also acceptable. For example, when a polyester film is constructed using polyethylene-2,6-naphthalenedicarboxylate, which has a high glass transition temperature or a high melting point, extrusion or stretching may be carried out at higher temperatures than the temperatures shown below.

<Film Formation/Extrusion>

The polyester base material in the invention is produced, for example, as follows.

First, a raw (unstretched) polyester sheet that constitutes the polyester base material is produced. In order to produce a raw polyester sheet, for example, pellets of the polyester prepared as described above are melted using an extruder, and the molten product is ejected through a nozzle (die) and then is molded into a sheet form through cooling and solidification. At this time, it is preferable to filter the polymer through a fiber-sintered stainless steel metal filter so as to remove unmelted matter in the polymer.

Furthermore, it is also another preferred aspect to add inorganic particles or organic particles, for example, inorganic particles of clay, mica, titanium oxide, calcium carbonate, kaolin, talc, wet silica, dry silica, colloidal silica, calcium phosphate, barium sulfate, alumina, zirconia and the like; organic particles constituted of acrylic resins, styrene-based resins, thermosetting resins, silicones, imide-based compounds and the like; and particles that are precipitated due to the catalyst and the like added during the polymerization reaction of the polyester (so-called internal particles), in order to impart good slipperiness, abrasion resistance, scratch resistance and the like to the surface of the polyester base material.

Furthermore, as long as the effects of the invention are not impaired, various additives, for example, a compatibilizing agent, a plasticizer, a weather resistant agent, an oxidation inhibitor, a thermal stabilizer, a gliding agent, an antistatic agent, a brightening agent, a colorant, an electroconductive agent, an ultraviolet absorber, a flame retardant, a flame retardant aid, a pigment and a dye, may also be added.

When such an additive or a terminal blocking agent is incorporated into the polyester, a method of mixing the terminal blocking agent directly with PET pellets, kneading the mixture using a vent type twin-screw kneading extruder which has been heated to a temperature of 270° C. to 275° C., and forming the kneading product into a high concentration master pellet, is effective.

Subsequently, the pellets of PET thus obtained are dried under reduced pressure for 3 or more hours at a temperature of 180° C., and then the dried pellets are supplied to an extruder which has been heated to a temperature of 265° C. to 280° C., more preferably to a temperature of 270° C. to 275° C., under a nitrogen gas stream or under reduced pressure so as to prevent the intrinsic viscosity from decreasing. The pellets are extruded through a slit die and cooled on a casting roll, and thus an unstretched film is obtained. In this case, it is preferable to use various filters, for example, filters made of materials such as sintered metals, porous ceramics, sand and iron wire, in order to remove foreign materials or degenerate polymer. Furthermore, a gear pump may also be provided if necessary, in order to improve metered supply. In the case of laminating a film, plural different polymers are melt laminated using two or more extruders and a manifold or a joint block. Melt lamination is used preferably when, for example, the reflective layer (white layer) is co-extruded.

The molten body (melt) extruded from an extruder as such is solidified on a casting (cooling) roll to which a temperature distribution has been imparted as described above, and thus a raw film (unstretched film) is obtained. A preferred temperature of the cooling roll is preferably from 10° C. to 60° C., more preferably from 15° C. to 55° C., and even more preferably from 20° C. to 50° C. At this time, in order to enhance the adhesive force between the melt and the cooling roll, an electrostatic application method, an air knife method, a method of forming a water film on the cooling roll, and the like may be preferably used.

Furthermore, according to the invention, when the melt is extruded onto a cast roll, it is preferable to set the linear velocity of the cast roll to 10 m/min or greater, more preferably from 15 m/min to 50 m/min, and even more preferably from 18 m/min to 40 m/min. If the linear velocity is equal to or less than this range, the retention time of the melt on the cast roll is lengthened, and especially, the temperature difference given by this method becomes even, so that the effects are reduced. On the other hand, if the linear velocity is greater than this range, thickness irregularity of the melt is prone to occur, and the temperature unevenness of the melt caused by the thickness irregularity exceeds the range described above, which is not preferable. In order to achieve such a velocity of the cast roll, it is necessary to set the kneading speed in the extruder to a high level, and in conventional methods, the AV is prone to increase due to the shear heat generation of the resin along with an increase in the speed of rotation of the screw. Such a phenomenon is prone to be manifested particularly conspicuously in the present invention which uses a resin having a high IV. For this reason, the invention is characterized by adding fine particles of a resin to the extruder. That is, the time point at which shear heat generation is most likely to occur is the initiation of melting during the early stage of kneading, and in this stage, pellets and the screw strongly rub against each other and generate heat. By adding fine particles of a resin at this stage, the friction between the pellets is reduced, and an increase in the AV is suppressed, so that the AV may be adjusted to the range of the invention. The size of these fine particles is preferably set to the range of from 200 meshes to 10 meshes, and the fine particles are obtained by crushing the pellets and sieving the crushed product. The amount of addition of these fine particles is preferably from 0.1% to 5%, more preferably from 0.3% to 4%, and even more preferably from 0.5% to 3%. When the amount of addition is less than this range, the effects described above are insufficient, and when the amount of addition is greater than this range, abrasion with the screw becomes too strong, and slippage occurs. Furthermore, thickness unevenness of the melt occurs due to a fluctuation in ejection, and the temperature distribution on the cast roll exceeds the range of the invention, which is not preferable.

<Film Formation/Longitudinal Stretching>

Subsequently, the raw film (unstretched film) is obtained above, is biaxially stretched in the longitudinal direction and the lateral direction and then heat treated. The method of performing biaxial stretching includes a sequential biaxial stretching method of performing stretching in the longitudinal direction and the width direction separately, as described above, a simultaneous biaxial stretching method of performing stretching in the longitudinal direction and the width direction at the same time, and further a combination method of the sequential biaxial stretching method and the simultaneous biaxial stretching method, and the like.

Here, the biaxially stretching, in which an unstretched film is stretched in the longitudinal direction by a longitudinal stretching machine with several rolls by using the difference of circumferential velocity of rolls (MD stretching) and then stretched in the lateral direction by a tentor (TD stretching), is described.

In the invention, while the unstretched film is firstly stretched with MD stretching, it is preferable to preheat sufficiently the unstretched film before MD stretching. A temperature of the preliminary heating is preferably from 40° C. to 90° C., more preferably from 50° C. to 85° C. and even more preferably from 60° C. to 80° C. The preheat is conducted by passing the raw film on a heat (temperature control) roll to which a temperature distribution in the lateral direction has been imparted as described above. A time of the preliminary heating is preferably from 1 second to 120 seconds, more preferably from 5 seconds to 60 seconds, and even more preferably 10 seconds to 40 seconds. MD stretching can be carried out by a single stage or a multistage.

In the single stage, the temperature of the MD stretching is from a glass-trasition temperature (Tg) to Tg+15° C. (more preferably to Tg+10° C.). The stretch ratio is preferably set to from 2.0 times to 6.0 times, more preferably from 3.0 times to 5.5 times, and even more preferably from 3.5 times to 5.0 times. It is preferable to be cooled with a group of rolls at a temperature of from 20° C. to 50° C. after stretching.

When a polyester has a larger IV and a higher molecular weight, a molecular mobility thereof is decreased, and oriented crystallization may hardly occur. Therefore, it is preferable to carry out the multistage stretching. First, stretching is carried out in a low temperature and thereafter a second stretching is carried out in a higher temperature, and thereby the oriented crystallization is achieved to obtain a high orientation. The first low temperature stretching (MD 1 stretching) is carried out by heated with a group of heating rolls in a range from (Tg−20° C.) to (Tg+10° C.), and more preferably from (Tg−10° C.) to (Tg+5° C.). The polyester film is stretched at a stretching ratio of preferably from 1.1 times to 3.0 times in the longitudinal direction, more preferably from 1.2 times to 2.5 times, and even more preferably from 1.5 times to 2.0 times, and then MD2 stretching is carried out in a range from (Tg+10° C.) to (Tg+50° C.) which is higher than MD1 stretching temperature. Preferable temperature at MD2 stretching is from (Tg+15° C.) to (Tg+30° C.) and MD2 stretching ratio is preferably from 1.2 times to 4.0 times, and more preferably from 1.5 times to 3.0 times. A total MD stretching ratio combined MD 1 stretching and MD2 stretching is preferably from 2.0 times to 6.0 times, more preferably from 3.0 times to 5.5 times, and even more preferably from 3.5 times to 5.0 times. The ratio of stretching ratio of the first stage and the second stage (refereed to a multistage ratio=the second stage/the first stage) is preferably from 1.1 times to 3 times, more preferably from 1.15 times to 2 times, and even more preferably from 1.2 times to 1.8 times.

It is preferable to be cooled with a group of rolls at a temperature of from 20° C. to 50° C. after stretching.

<Film Formation/Lateral Stretching>

Subsequently, the film is stretched in the width direction by using a tenter (also referred to as a stentor) at a stretch ratio of from 2.0 times to 6.0 times, preferably from 3.0 times to 5.5 times, and more preferably from 3.5 times to 5.0 times. A range of temperature of stretching is (Tg) to (Tg+50° C.) and preferably from (Tg) to (Tg+30° C.) (TD stretching). Here, Tg represents a glass transition temperature of a material (polyester). Tg may be measured based on JIS K7121, ASTM D3418-82 or the like. In the invention, for example, Tg is measured with differential scanning calorimeter (DSC) manufactured by SHIMADZU CO. LTD. Specifically, 10 mg of a polymer such as polyester or the like, as a sample, are weighed and set in an aluminum pan, and while raising the temperature from room temperature to the final temperature of 300° C. at a temperature increase rate of 10° C./min, the heat quantity versus temperature is measured using a DSC device; and the temperature of the peak top of the DSC curve is designated as the glass transition temperature.

The thickness of the polyester base material is preferably from about 25 μm to about 300 μm. When the thickness is 25 μm or more, a satisfactory mechanical strength may be obtained, and when the thickness is 300 μm or less, it is advantageous in terms of cost.

Particularly, a polyester base material has a tendency that as the thickness increases, hydrolysis resistance is deteriorated and durability decreases during a long-term use. Thus, in the present invention, in a case in which the thickness of the polyester base material is from 120 μm to 300 μm and the carboxyl group content in the polyester is from 2 eq/t to 15 eq/t, an effect of enhancing the durability against moisture and heat is further achieved.

In a preferable embodiment, the polyester base material is surface-treated by a corona treatment (which is also referred to as corona discharge treatment), a flame treatment, a low pressure plasma treatment, an atmospheric pressure plasma treatment, or an ultraviolet treatment. When such a surface treatment is carried out, the adhesiveness in the case of being exposed to a hot and humid environment can be further improved. Above all, in particular, when a corona treatment is applied, a more excellent effect of improving adhesiveness may be obtained.

According to these surface treatments, the number of carboxyl groups or hydroxyl groups is increased at a surface of the polyester base material, whereby adhesiveness is improved. Further, by the use of a crosslinking agent (in particular, an oxazoline-based or carbodiimide-based crosslinking agent having high reactivity with a carboxyl group) in combination, a stronger adhesiveness can be obtained. This phenomenon is more remarkably realized in the case of a corona treatment.

(Polymer Layer)

The polymer layer according to the invention is a layer disposed on the polyester base material so as to be in contact with the surface of the polyester base material, or via another layer. The polymer layer is constituted by using at least a specific composite polymer containing, in the molecule, non-siloxane-based structural units and (poly)siloxane structural units represented by the following Formula (1). Since adhesion to the polyester base material and interlayer adhesiveness (in particular, adhesiveness to a sealing material provided on a cell-side base board) are improved by the configuration including the composite polymer, the polymer layer according to the invention is preferably formed directly on the polyester base material. Further, since a polymer layer having resistance to storage under moisture and heat is formed, it is also preferable to use the polymer layer as an outermost layer that is exposed to the external environment, that is, a back layer.

Depending on the situation, the polymer layer may be constructed by further using another component, and the constituent component differs according to the intended use. The polymer layer can constitute a colored layer which has a function of reflecting sunlight or applying external appearance design or the like, a back layer which is placed on the opposite side from the sunlight incident side, or the like.

In a case in which the polymer layer is constructed as, for example, a reflective layer that reflects sunlight to the incident side thereof, the polymer layer may further contain a colorant such as a white pigment. In this case, the reflective layer is formed as a polymer layer including a composite polymer. In the case of disposing two or more polymer layers on a polyester base material, a laminate structure of: white layer (polymer layer)/polymer layer/polyester base material may be used. The white layer may be constructed as a reflective layer. It is possible to further enhance the adhesiveness and adhesion of the reflective layer in the polymer sheet.

—Composite Polymer—

The polymer layer according to the present invention includes at least one composite polymer which contains, in the molecule, 15% by mass to 85% by mass of (poly)siloxane structural units represented by the following Formula (1) and 85% by mass to 15% by mass of non-siloxane-based structural units. By the inclusion of this composite polymer, adhesiveness to a polyester base material which is a support, interlayer adhesiveness, or adhesiveness to the constituent base material of a cell-side base board (for example, a sealing material such as EVA), that is, peeling resistance and shape stability which is easily deteriorated by the application of heat or moisture, can be improved dramatically as compared with conventional polymer layers.

The composite polymer according to the invention is a block copolymer in which a polysiloxane and at least one polymer are copolymerized. The polysiloxane and the polymer that is copolymerized may be respectively composed of a single compound, or may be composed of two or more kinds.

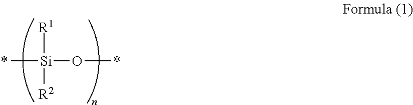

In Formula (1), R¹ and R² each independently represent a hydrogen atom, a halogen atom, or a monovalent organic group. Herein, R¹ and R² may be identical with or different from each other. Plural R¹s may be identical with or different from each other, and plural R²s may be identical with or different from each other. n represents an integer of 1 or more.

In the “—(Si(R¹)(R²)—O)ₙ—” moiety ((poly)siloxane structural unit represented by Formula (1) above), which is a polysiloxane segment in the composite polymer, R¹ and R² may be identical with or different from each other, and respectively represent a hydrogen atom, a halogen atom, or a monovalent organic group capable of covalent bonding with a Si atom.

The moiety “—(Si(R¹)(R²)—O)ₙ—” is a polysiloxane segment derived from various polysiloxanes having a straight chain, branched or cyclic structure.

Examples of the halogen atom represented by R¹ and R² include a fluorine atom, a chlorine atom, and an iodine atom.

The “monovalent organic group capable of covalent bonding with a Si atom,” which is represented by R¹ and R², may be unsubstituted or may be substituted. Examples of the monovalent organic group include an alkyl group (for example, a methyl group or an ethyl group), an aryl group (for example, a phenyl group), an aralkyl group (for example, a benzyl group or a phenylethyl group), an alkoxy group (for example, a methoxy group, an ethoxy group, or a propoxy group), an aryloxy group (for example, a phenoxy group), a mercapto group, an amino group (for example, an amino group or a diethylamino group), and an amido group.

Among them, from the viewpoints of adhesiveness to an adjacent material such as a polyester base material, and durability in a hot and humid environment, R¹ and R² are each independently preferably a hydrogen atom, a chlorine atom, a bromine atom, an unsubstituted or substituted alkyl group having 1 carbon atom to 4 carbon atoms (particularly, a methyl group or an ethyl group), an unsubstituted or substituted phenyl group, an unsubstituted or substituted alkoxy group, a mercapto group, an unsubstituted amino group, or an amido group, and more preferably an unsubstituted or substituted alkoxy group (preferably, an alkoxy group having 1 to 4 carbon atoms), from the viewpoint of durability in a hot and humid environment.

n is preferably 1 to 5,000, and more preferably 1 to 1,000.

The proportion of the —(Si(R¹)(R²)—O)ₙ— moiety (polysiloxane moiety represented by Formula (1)) in the composite polymer is 15% by mass to 85% by mass relative to the total mass of the composite polymer, and inter alia, from the viewpoints of adhesiveness to the polyester base material and durability in a hot and humid environment, the proportion is more preferably in the range of 20% by mass to 80% by mass.

If the proportion of the polysiloxane moiety is less than 15% by mass, the adhesiveness to the polyester base material and the adhesion durability upon exposure to a hot and humid environment are deteriorated. If the proportion is more than 85% by mass, an applying liquid becomes unstable.

There are no particular limitations on the polymer structural moiety that is copolymerized with the polysiloxane moiety as far as the polymer structural moiety contains no polysiloxane moiety, and the polymer structural moiety may be any polymer segment derived from any arbitrary polymer. Examples of a polymer that serves as a precursor of the polymer segment (precursor polymer) include various polymers such as a vinyl-based polymer, a polyester-based polymer, and a polyurethane-based polymer. From the viewpoints that preparation is easy and resistance to hydrolysis is excellent, a vinyl-based polymer and a polyurethane-based polymer are preferable, a vinyl-based polymer is particularly preferable.

Representative examples of the vinyl-based polymer include various polymers such as an acrylic polymer, a carboxylic acid-vinyl ester-based polymer, an aromatic vinyl-based polymer and a fluoro-olefin-based polymer. Among them, from the viewpoints of the degree of freedom in design, an acrylic polymer (that is, an acrylic polymer structural moiety as the non-polysiloxane structural moiety) is particularly preferable.

In addition, the polymers that constitute the polymer structural moiety may be used alone, or two or more kinds may be used in combination.

Furthermore, the precursor polymer that constitutes the polymer structural moiety preferably contains at least one of an acid group and a neutralized acid group, and/or a hydrolyzable silyl group. Among such precursor polymers, a vinyl-based polymer can be prepared by using various methods such as, for example, (a) a method of copolymerizing a vinyl-based monomer containing an acid group, and a vinyl-based monomer containing a hydrolyzable silyl group and/or a silanol group, with a monomer capable of being copolymerized with these monomers; (2) a method of allowing a vinyl-based polymer containing a hydroxyl group and a hydrolyzable silyl group and/or a silanol group, which has been prepared in advance, to react with a polycarboxylic acid anhydride; and (3) a method of allowing a vinyl-based polymer containing an acid anhydride group and a hydrolyzable silyl group and/or a silanol group, which has been prepared in advance, to react with a compound having active hydrogen (water, alcohol, amine or the like).

Such a precursor polymer can be produced and obtained by using the method described in, for example, paragraphs [0021] to [0078] of JP-A No. 2009-52011.

The polymer layer according to the invention may use the composite polymer alone as a binder, or may use the composite polymer in combination with another polymer. When another polymer is used in combination, the proportion of the composite polymer according to the invention is preferably 30% by mass or greater, and more preferably 60% by mass or greater, based on the total amount of binders. When the proportion of the composite polymer is 30% by mass or greater, the polymer layer is excellent in the adhesiveness to the polymer base material and the durability in a hot and humid environment.

A weight average molecular weight of the composite polymer is preferably in a range of 5,000 to 100,000, and more preferably in a range of 10,000 to 50,000.

For the preparation of the composite polymer, methods such as (i) a method of allowing a precursor polymer to react with the polysiloxane having a structure of “—(Si(R¹)(R²)—O)ₙ—”, and (ii) a method of subjecting a silane compound having the structure of “—(Si(R¹)(R²)—O)ₙ—” in which R¹ and/or R² is a hydrolyzable group, to hydrolysis and condensation in the presence of a precursor polymer, can be used.

Examples of the silane compound used in the method (ii) include various silane compounds, but an alkoxysilane compound is particularly preferable.

In the case of preparing a composite polymer by the method (i), the composite polymer can be prepared by, for example, allowing a mixture of a precursor polymer and a polysiloxane to react, while optionally adding water and a catalyst, at a temperature of about 20° C. to 150° C. for about 30 minutes to 30 hours (preferably, at 50° C. to 130° C. for 1 hour to 20 hours). As the catalyst, various silanol condensation catalysts such as an acidic compound, a basic compound, and a metal-containing compound, can be added.

Furthermore, in the case of preparing a composite polymer by the method (ii), the composite polymer can be prepared by, for example, adding water and a silanol condensation catalyst to a mixture of a precursor polymer and an alkoxysilane compound, and subjecting the mixture to hydrolysis and condensation at a temperature of about 20° C. to 150° C. for about 30 minutes to 30 hours (preferably, at 50° C. to 130° C. for 1 to 20 hours).

—Crosslinking Agent—

In the present invention, the polymer layer preferably has a structural portion derived from a crosslinking agent that crosslinks the composite polymer. Namely, the polymer layer can be formed by using a crosslinking agent capable of crosslinking the composite polymer. When the composite polymer is crosslinked by a crosslinking agent, the adhesiveness after a lapse time under moisture and heat, specifically, adhesion with respect to the polyester base material and interlayer adhesion in the case of being exposed to a hot and humid environment can be further improved.

Examples of the crosslinking agent include epoxy-based, isocyanate-based, melamine-based, carbodiimide-based and oxazoline-based crosslinking agents. Among them, a crosslinking agent of a carbodiimide-based compound or an oxazoline-based compound is preferable.

Specific examples of the oxazoline-based crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane) sulfide, and bis-(2-oxazolinylnorbornane) sulfide. Furthermore, (co)polymers of these compounds are also used with preference.

As the oxazoline-based crosslinking agent, EPOCROS K2010E, EPOCROS K2020E, EPOCROS K2030E, EPOCROS WS-500, EPOCROS WS-700 (trade names, all manufactured by Nippon Shokubai co., Ltd.) and the like can also be used.

Specific examples of the carbodiimide-based crosslinking agent may include dicyclohexylmethane carbodiimide, tetramethylxylylene carbodiimide, dicyclohexylmethane carbodiimide, and the like. Further, the carbodiimide compounds described in JP-A No. 2009-235278 are also preferable. Specifically, as a carbodiimide-based crosslinking agent, commercially available products such as CARBODILITE SV-02, CARBODILITE V-02, CARBODILITE V-02-L2, CARBODILITE V-04, CARBODILITE E-01, or CARBODILITE E-02 (all trade names, manufactured by Nisshinbo Chemical, Inc.) can also be used.

In the polymer layer, the proportion by mass of the structural portion derived from the crosslinking agent relative to the composite polymer is preferably from 1% by mass to 30% by mass, and more preferably from 5% by mass to 20% by mass. When the content of the crosslinking agent is 1% by mass or higher, the polymer layer has excellent strength and excellent adhesiveness after a lapse of time under moisture and heat. When the content of the crosslinking agent is 30% by mass or lower, a prolonged pot life of the coating liquid can be maintained.

In the polymer sheet of the present invention, since the polymer layer includes a composite polymer as described above, adhesion with respect to the polyester base material is improved and interlayer adhesiveness (particularly, adhesiveness to a sealing material provided on a cell-side base board, when the polymer sheet of the invention is used as a backsheet) is improved. Further, resistance to deterioration (adhesion durability) in a hot and humid environment is excellent. For this reason, it is also preferable to provide the polymer layer as the outermost layer that is disposed at the position farthest from the polyester base material. Specific examples include a back layer which is disposed on the side (rear side) opposite from the side (front side) facing a cell-side base board equipped with a solar cell element; a reflective layer which has light reflectivity and is disposed so as to be in contact with a sealing material that seals a solar cell element of a cell-side base board; and the like.

The polymer layer may be provided as one layer, or plural polymer layers may be formed.

Generally, the thickness of one polymer layer is preferably from 0.3 μm to 22 μm, more preferably from 0.5 μm to 15 μm, even more preferably in a range of from 0.8 μm to 12 μm, particularly preferably in a range of from 1.0 μm to 8 μm, and most preferably in a range of from 2 μm to 6 μm. When the thickness of the polymer layer is 0.3 μm or more, or further, 0.8 μm or more, moisture hardly penetrates from the surface of the polymer layer to the inside when exposed to a hot and humid environment, and thus moisture hardly reaches the interface between the polymer layer and the polyester base material, so that the adhesiveness is remarkably improved. Further, when the thickness of the polymer layer is 22 μm or less, or further, 12 μm or less, the polymer layer itself hardly becomes brittle, and destruction of the polymer layer when exposed to a hot and humid environment is less likely to occur, so that the adhesiveness is improved.

Particularly, in a case in which the polymer layer in the invention includes the composite polymer and a crosslink structure in which polymer molecules of the composite polymer are crosslinked by the crosslinking agent, wherein the proportion of the structural portion derived from the crosslinking agent relative to the composite polymer is from 1% by mass to 30% by mass, and the thickness of the polymer layer is from 0.8 μm to 12 μm, the effect on improvement of adhesiveness after a lapse of time under moisture and heat is excellent.

—Back Layer—

When the polymer sheet for a solar cell of the present invention is used as a backsheet for a solar cell, the polymer layer in the invention may be constructed as a back layer. In this case, the back layer may be configured to include the composite polymer and further, as needs arise, other components such as various additives. In a solar cell having a laminate structure of: cell-side base board (=transparent base board (a glass base board or the like) on the sunlight incident side/element structural portion containing a solar cell element)/backsheet for a solar cell, the back layer is a rear face protective layer which is disposed on the opposite side of the polyester base material, which is a support, from the side facing the cell-side base board. The back layer may have a monolayer structure, or may have a structure in which two or more layers are laminated. Since the back layer contains the composite polymer, the adhesion with respect to the polyester base material or the interlayer adhesion in a case in which the back layer is composed of two ore more layers is improved, and at the same time, resistance to deterioration in a hot and humid environment is obtained. Therefore, it is preferable that the back layer, that is the polymer layer according to the present invention, is disposed as the outermost layer, which is a layer disposed at the farthest position from the polyester base material.

In the case of providing two or more back layers, the two or more layers each may be a polymer layer containing the composite polymer or both the composite polymer and the crosslinking agent, or only one of the back layers may be a polymer layer containing the composite polymer or both the composite polymer and the crosslinking agent.

Above all, from the viewpoint of improving the adhesion durability in a hot and humid environment, it is preferable that at least the back layer (first back layer) that contacts the polyester base material is a polymer layer containing the composite polymer or both the composite polymer and the crosslinking agent. Further, in this case, the second back layer which is further provided on the first back layer on the polyester base material may be a layer that does not contain the composite polymer containing (poly)siloxane structural units represented by Formula (1) above and non-polysiloxane structural units. However, in this case, it is preferable that the second back layer does not contain a polysiloxane homopolymer, from the viewpoint of forming a uniform film of a resin alone without any voids to prevent moisture penetration through voids between the polymer and the pigment, thereby enhancing the adhesiveness in a hot and humid environment.

Examples of additional components which may be contained in the back layer include a surfactant, a filler, and the like, as described below. Further, the back layer may contain pigments which are used in the colored layer. Details and preferable embodiments of these additional components and pigments are described below.

—Colored Layer—

In a case in which the polymer layer according to the present invention is constructed as a colored layer (preferably, as a reflective layer), the colored layer further contains a pigment, in addition to the composite polymer. The colored layer may further include additional components such as various additives, as necessary.

The functions of the colored layer may include, firstly, an enhancement of the power generation efficiency of solar cell modules by reflecting a portion of incident light which passes through a photovoltaic cell and reaches the backsheet without being used in the power generation, to return the portion of light to the photovoltaic cell; and secondly, an enhancement of the decorative properties of the external appearance when the solar cell module is viewed from the side through which sunlight enters (front surface side), for example, in a case in which a polymer sheet according to the invention for a solar cell is applied as a backsheet for a solar cell. Generally, when a solar cell modules is viewed from the front surface side, the backsheet is seen around the photovoltaic cell. Thus, when a colored layer is provided in the backsheets, the decorative properties of the backsheet are improved, and thereby the appearance may be improved.

(Pigment)

The colored layer in the invention contains at least one pigment.

As the pigment, for example, an inorganic pigment such as titanium dioxide, barium sulfate, silicon oxide, aluminum oxide, magnesium oxide, calcium carbonate, kaolin, talc, ultramarine blue, Prussian blue, or carbon black; or an organic pigment such as phthalocyanine blue or phthalocyanine green can be appropriately selected and incorporated.

In the case where a polymer layer is constructed as a reflective layer which reflects the light that has entered a solar cell and passed through the photovoltaic cell, and returns the light to the photovoltaic cell, it is preferable that the colored layer contain a white pigment among the pigments. Preferable examples of the white pigment include titanium dioxide, barium sulfate, silicon oxide, aluminum oxide, magnesium oxide, calcium carbonate, kaolin, and talc.

The content of the pigment in the colored layer is preferably in the range of 2.5 to 8.5 g/m². When the content of the pigment is 2.5 g/m² or greater, necessary coloration may be achieved, and a desired reflectance or decorative properties may be effectively imparted to the colored layer. Furthermore, when the content of the pigment in the colored layer is 8.5 g/m² or less, the surface state of the colored layer may be easily maintained satisfactory, and the film strength is more excellent. Among these values, the content of the pigment is more preferably in the range of 4.5 to 8.0 g/m².

The volume average particle diameter of the pigment is preferably 0.03 μm to 0.8 μm, and more preferably about 0.15 μm to 0.5 μm. When the average particle diameter is in the range mentioned above, the efficiency of light reflection is high. The average particle diameter is a value measured with a laser diffraction/scattering type particle diameter distribution measuring apparatus LA950 (trade name, manufactured by Horiba, Ltd.).

When the colored layer include a polymer layer, a content of the binder component (including the composite polymer above) is preferably in the range of 15% by mass to 200% by mass, and more preferably in the range of 17% by mass to 100% by mass, based on the content of the pigment. When the content of the binder is 15% by mass or more, the strength of the colored layer is sufficiently obtained, and when the content is 200% by mass or less, the reflectance or decorative properties can be maintained satisfactorily.

—Additives—

The polymer layer in the invention may further contain a surfactant, a filler, and the like as necessary.

The surfactant such as known anionic or nonionic surfactants can be used. When a surfactant is added in the polymer layer, the amount added is preferably 0.1 mg/m² to 15 mg/m², and more preferably 0.5 mg/m² to 5 mg/m². When the amount of the surfactant added is 0.1 mg/m² or greater, the occurrence of cissing is suppressed, and satisfactory layer formation may be achieved. When the amount added is 15 mg/m² or less, the adhesion can be satisfactorily achieved.

The polymer layer in the invention may further contain a filler. The amount of addition of the filler is preferably 20% by mass or less, and more preferably 15% by mass or less with respect to the content of the binder in the polymer layer. When the amount of addition of the filler is 20% by mass or less, the surface state of the colored layer may be maintained more satisfactorily.

—Physical Properties—

In the case of preparing a reflective layer by adding a white pigment as a pigment to the colored layer, it is preferable that a reflectance of light having a wavelength of 550 nm on the surface of the side having thereon the colored layer and a readily-adhesive layer is 75% or greater. Note that, a light reflectance is a ratio of the amount of light that enters through the surface of the readily-adhesive layer, is reflected by the reflective layer, and exits again through the readily-adhesive layer, relative the amount of incident light. Here, the light having a wavelength of 550 nm is used as the light having a representative wavelength.

When the light reflectance is 75% or greater, light that has passed through the cell and has entered into inside may be effectively returned to the cell, and thus, a large effect of enhancing the power generation efficiency may be achieved. The light reflectance can be adjusted to 75% or greater, by controlling the content of the colorant in the range of from 2.5 g/m² to 30 g/m².

(Additional Functional Layer)

The polymer sheet for a solar cell of the present invention may have additional functional layers, other than the polyester base material and the polymer layer. As the additional functional layer, an under coating layer or a readily-adhesive layer may be provided.

[Under Coating Layer]

In the polymer sheet for a solar cell of the invention, an under coating layer may be provided between the polyester base material (support) and the polymer layer. The thickness of the under coating layer is preferably in a range of 2 μm or less, more preferably in a range of from 0.05 μm to 2 μm, and more preferably in a range of from 0.1 μm to 1.5 μm. When the thickness is 2 μm or less, the surface state may be maintained satisfactorily. Further, when the thickness is 0.05 μm or more, a necessary adhesiveness may be easily ensured.

The under coating layer may contain a binder. Examples of the binder, which can be used, include polyester, polyurethane, an acrylic resin, polyolefin, and the like. Further, other than the binder, a crosslinking agent such as an epoxy-based, isocyanate-based, melamine-based, carbodiimide-based, or oxazoline-based crosslinking agent, a surfactant such as an anionic or nonionic surfactant, a filler such as silica, or the like may be added to the under coating layer.

There are no particular limitations on the method for coating the under coating layer and the solvent of the coating solution to be used.

In regard to the coating method, for example, a gravure coater or a bar coater can be used.

The solvent used in the coating liquid may be water, or may be an organic solvent such as toluene or methyl ethyl ketone. The solvent may be used singularly, or in a combination of two or more kinds thereof.

Further, concerning coating, the coating liquid may be coated on a polyester base material that has been biaxially stretched, or a method of coating the coating liquid on a polyester base material that has been uniaxially stretched, and then stretching the polyester base material in the direction different from the direction of the initial stretching may be adopted. Moreover, the coating liquid may be coated on a base material before stretching, and then the base material may be stretched in two directions.

When the polymer sheet for a solar cell of the present invention is used as a backsheet for a solar cell, the backsheet for a solar cell can be produced by appropriately selecting a method, as far as the method is capable of disposing a polymer layer, that contains the above-described specific composite polymer (composite polymer containing non-siloxane-based structural units and siloxane structural units represented by Formula (1)), to be in contact with the sealing material of the cell-side base board in which a solar cell element is sealed with a sealing material. Above all, formation of the polymer layer can be most preferably carried out by the method for producing a polymer sheet for a solar cell of the present invention, which is shown below.

[Colored Layer]

The polymer sheet of the present invention may be provided with a colored layer (preferably, a reflective layer) that does not substantially contain the composite polymer. In this case, the polymer sheet may be suitably constructed by providing a polymer layer containing the composite polymer between the colored layer (particularly, a reflective layer) and the polyester base material. The colored layer in this case contains at least a polymer component other than the composite polymer, and a pigment, and may further contain, as necessary, other components such as various additives.

Here, details of the pigment and various additives are as described above in the description on the case in which the polymer layer is formed as a colored layer. There is no particular limitation concerning the polymer component other than the composite polymer, and the polymer component may be appropriately selected according to the purpose or the like.

The expression “does not substantially contain” means that the composite polymer is not positively contained in the colored layer, and specifically means that the content of the composite polymer in the colored layer is 15% by mass or lower. The case in which the colored layer does not contain the composite polymer (the content is 0 (zero) % by mass) is preferable.

When a reflective layer is provided over the polyester base material, as is described above, the invention is not limited to an embodiment in which the reflective layer contains the composite polymer, and an embodiment in which one or two or more polymer layers are provided between a reflective layer, that does not substantially contain the composite polymer, and the polyester base material may also be adopted. In this case, by providing a polymer layer containing the composite polymer between the polyester base material and the reflective layer, the adhesiveness and adhesion between the reflective layer and the polyester base material can be enhanced, and water resistance can be further enhanced. Thereby, deterioration in weather resistance caused by adhesion failure may be prevented.

<Production of Polymer Sheet for Solar Cell>

As described above, the polymer sheet for a solar cell of the invention may be produced by any method as long as the method is a method capable of forming, on the polyester base material described above, the polymer layer according to the present invention and, as needs arise, a colored layer, an under coating layer, or the like. In the present invention, the polymer sheet for a solar cell of the invention can be suitably produced by a production method (a method for producing a polymer sheet for a solar cell of the present invention) including a step of coating, on a polyester base material having a carboxyl group content of 15 eq/t or less, a minute endothermic peak temperature Tmeta (° C.) of 220° C. or lower as determined by differential scanning calorimetry, and an average elongation retention ratio of 10% or more as determined after being allowed to stand under the conditions of a temperature of 125° C. and a relative humidity of 100% RH for 72 hours, a coating liquid containing a composite polymer, which contains, in the molecule, 15% by mass to 85% by mass of siloxane structural units represented by Formula (1) above and 85% by mass to 15% by mass of non-siloxane-based structural units, and preferably a crosslinking agent (and, as necessary, a coating liquid for readily-adhesive layer or the like), to form at least one polymer layer.

Note that, the coating liquid for polymer layer is a coating liquid including at least a composite polymer as described above. Details of the polyester base material, and the composite polymer and other components which constitute the respective coating liquids are as described above.

Preferable coating methods are also as described above. For example, a gravure coater or a bar coater can be used. Further, in the coating step according to the present invention, a polymer layer (for example, a colored layer (preferably, a reflective layer) or a back layer) can be formed on the polyester base material by coating a coating liquid for polymer layer directly, or through an under coating layer having a thickness of 2 μm or less, on the surface of the polyester base material.

Formation of the polymer layer can be carried out by a method of pasting a sheet-like polymer member onto the polyester base material, a method of co-extruding the polymer layer at the time of forming the polyester base material, a method based on coating, or the like. Among them, a method based on coating is preferable from the viewpoints that the method is convenient, and is possible to form a uniform thin film. In the case of forming the polymer layer by coating, in regard to the coating method, known coating methods using, for example, a gravure coater or a bar coater can be used.

The coating liquid may be an aqueous system using water as a coating solvent, or a solvent-based system using an organic solvent such as toluene, methyl ethyl ketone or the like. Among them, from the viewpoint of environmental load, it is preferable to use water as the solvent. The coating solvent may be used singularly, or in a combination of two or more kinds thereof.

The coating liquid for polymer layer is preferably an aqueous coating liquid in which 50% by mass or more, preferable 60% by mass or more, of the solvent contained in the coating liquid is water. Aqueous coating liquids are preferable in view of environmental load, and when the proportion of water is 50% by mass or more, it is advantageous since environmental load becomes particularly small. From the viewpoint of environmental load, a larger proportion of water in the coating liquid for polymer layer is desirable, and the case of containing water in an amount of 90% by mass or more of the total amount of solvents is more preferable.

After coating, a drying step in which drying is carried out under desired conditions may be provided.

<Backsheet for Solar Cell>

The backsheet for a solar cell of the present invention is a backsheet for a solar cell, which is disposed to be in contact with the sealing material of the cell-side base board in which a solar cell element is sealed with a sealing material, and is constructed by using the above-described polymer sheet for a solar cell of the present invention, or a polymer sheet for a solar cell which is produced by the above-described method for producing a polymer sheet for a solar cell of the present invention.

For example, the polymer sheet for a solar cell of the invention may be used as it is as a backsheet for a solar cell, or a readily-adhesive layer or a barrier layer described below may be added to the polymer sheet for a solar cell of the invention.

Further, the backsheet for a solar cell of the invention may have two or more polymer sheets of the invention. In this case, it is preferable that a backsheet for a solar cell is constructed by pasting the polymer sheet for a solar cell of the invention and the polymer sheet for a solar cell of the invention with an adhesive. As the adhesive, for example, a mixture obtained by mixing LX 660 (K) [trade name, manufactured by DIC Corp.; adhesive] with 10 parts of a curing agent KW75 [trade name, manufactured by DIC Corp.; adhesive] may be used. The laminated body of polymer sheets for a solar cell obtained by pasting may be further subjected to hot press adhesion using a press machine such as a vacuum laminator [vacuum laminating machine, manufactured by Nisshinbo Industries, Inc.].

[Readily-Adhesive Layer]

The backsheet of the present invention may further have a readily-adhesive layer on a surface of a side of the polyester base material opposite from the face at which the polymer layer is provided, or on the polymer layer (particularly, on the reflective layer). The readily-adhesive layer is a layer intended to firmly adhere the backsheet to the sealing material that seals the solar cell element (hereinafter, may also be referred to as “power generating element”) of the cell-side base board (the main body of the cell).

The readily-adhesive layer can be constructed by using a binder and inorganic fine particles, and may further include, as necessary, additional components such as additives. It is preferable that the readily-adhesive layer is constituted so as to have an adhesive power of 5 N/cm or more with respect to the sealing material {for example, ethylene-vinyl acetate (EVA) copolymer}, polyvinyl butyral (PVB), an epoxy resin, or the like) that seals the power generation elements of the cell-side base board. When the adhesive power is 5 N/cm or more, moisture and heat resistance capable of maintaining the adhesiveness may be easily obtained. The adhesive power is preferably 10 N/cm or more, and more preferably 20 N/cm or more.

Note that, the adhesion is may be adjusted by using a method of regulating the amount of the binder and inorganic fine particles in the readily-adhesive layer, a method of applying a corona treatment to a face that is bonded to the sealing material of the backsheet, or other methods.

—Binder—

The readily-adhesive layer may contain at least one binder.

Examples of the binder that is suitable for the readily-adhesive layer include a polyester, a polyurethane, an acrylic resin, and a polyolefin. Among them, an acrylic resin or a polyolefin is preferable from the viewpoint of durability. Furthermore, a composite resin of acrylic resin ingredient and silicone resin ingredient is also preferable as the acrylic resin.

Preferable examples of the binder include, as specific examples of the polyolefin, CHEMIPEARL S-120 and S-75N (trade names, all manufactured by Mitsui Chemicals, Inc.); as specific examples of the acrylic resin, JURYMER ET-410 and SEK-301 (trade names, all manufactured by Nihon Junyaku Co., Ltd.); and as specific examples of the composite resin of acrylic resin ingredient and silicone resin ingredient, CERANATE WSA1060 and WSA1070 (trade names, all manufactured by DIC Corp.), H7620, H7630 and H7650 (trade names, all manufactured by Asahi Kasei Chemicals Corp.).

The content of the binder in the readily-adhesive layer is preferably in the range of 0.05 g/m² to 5 g/m². Inter alia, the content is more preferably in the range of 0.08 g/m² to 3 g/m². If the content of the binder is 0.05 g/m² or more, a desired adhesive power is easily obtained, and if the content is 5 g/m² or less, a satisfactory surface state can be obtained.

—Fine Particles—

The readily-adhesive layer may contain at least one kind of inorganic fine particles.

Examples of the inorganic fine particles include fine particles of silica, calcium carbonate, magnesium oxide, magnesium carbonate and tin oxide. Among them, the fine particles of tin oxide and silica are preferable from the viewpoint that the decrease in adhesiveness is small when the readily-adhesive layer is exposed to a hot and humid atmosphere.

The particle size of the inorganic fine particles is preferably about 10 nm to 700 nm, and more preferably about 20 nm to 300 nm, as the volume average particle size. When the particle size is in this range, more satisfactory adhesiveness can be obtained. The particle size is a value measured with a laser diffraction/scattering type particle size distribution analyzer LA950 (trade name, manufactured by Horiba, Ltd.).

There are no particular limitations on the shape of the inorganic fine particles, and the inorganic fine particles having any of a spherical shape, an amorphous shape, a needle shape and the like can be used.

A content of the inorganic fine particles is in the range of 5% by mass to 400% by mass, based on the binder in the readily-adhesive layer. If the content of the inorganic fine particles is less than 5% by mass, satisfactory adhesiveness cannot be retained when the readily-adhesive layer is exposed to a hot and humid atmosphere, and if the content is greater than 400% by mass, the surface state of the readily-adhesive layer is deteriorated.

Inter alia, the content of the inorganic fine particles is preferably in the range of 50% by mass to 300% by mass.

<Crosslinking Agent>

The readily-adhesive layer can contain at least one crosslinking agent.

Examples of the crosslinking agent that is suitable for the readily-adhesive layer include epoxy-based, isocyanate-based, melamine-based, carbodiimide-based and oxazoline-based crosslinking agents. Among them, from the viewpoint of securing adhesiveness after a lapse of time under moisture and heat, an oxazoline-based crosslinking agent is particularly preferable.

As the specific examples of the oxazoline-based crosslinking agent, the same crosslinking agents as ones above described usable for the specific polymer layer are also preferably exemplified for readily-adhesive layer.

A content of the crosslinking agent in the readily-adhesive layer is preferably 5% by mass to 50% by mass based on the binder in the readily-adhesive layer, and inter alia, more preferably 20% by mass to 40% by mass. When the content of the crosslinking agent is 5% by mass or greater, a satisfactory crosslinking effect is obtained, and the strength of the readily-adhesive layer and adhesiveness of the readily-adhesive layer between the adjacent layer can be maintained. When the content is 50% by mass or less, a prolonged pot life of the coating liquid can be maintained.

—Additives—

The readily-adhesive layer according to the invention may optionally contain a known matting agent such as polystyrene, polymethyl methacrylate or silica; a known anionic or nonionic surfactant; and the like.

—Method of Forming Readily-Adhesive Layer—

The formation of the readily-adhesive layer may be carried out by using a method of pasting a sheet-like polymer member having easy adhesiveness to a base material, or a method based on coating. Among them, the method based on coating is preferable from the viewpoints that the method is convenient, and it is possible to form a uniform thin film. In regard to the coating method, known coating methods using, for example, a gravure coater or a bar coater can be used.

The coating solvent used in the preparation of the coating liquid may be water, or may be an organic solvent such as toluene or methyl ethyl ketone. The coating solvent may be used singularly, or in a combination of two or more kinds thereof.

There are no particular limitations on the thickness of the readily-adhesive layer, but the thickness is usually preferably 0.05 μm to 8 μm, and more preferably in the range of 0.1 μm to 5 μm. When the thickness of the readily-adhesive layer is 0.05 μm or thicker, the necessary adhesiveness can be suitably obtained, and when the thickness is 8 μm or thiner, the surface state becomes more satisfactory.

—Physical Properties—

Further, the backsheet for a solar cell of the invention preferably has an adhesive power to the sealing material after storage for 48 hours under an atmosphere of 120° C. and 100% RH of 75% or more, with respect to the adhesive power to the sealing material before storage. As described above, the backsheet for a solar cell of the invention has a readily-adhesive layer that includes a predetermined amount of a binder and a predetermined amount of inorganic fine particles with respect to the binder and has an adhesive power of 10 N/cm or more to the EVA sealing material and therefore, even after the storage described above, an adhesive power of 75% or more of the adhesive power before storage is obtained. Accordingly, when prepared as a solar cell module, peeling of the backsheet and deterioration in power generation performance due to the peeling are suppressed, and the long-term durability is further enhanced.

[Barrier Layer]

It is also preferable that the backsheet for a solar cell of the invention has a barrier layer. By having a barrier layer, permeation of water or gas into the backsheet for a solar cell can be prevented. The water vapor permeation amount (water-vapor permeability) of the barrier layer is preferably from 10° g/m²·d to 10⁻⁶ g/m²·d, more preferably from 10⁻¹ g/m²·d to 10⁻⁵ g/m²·d, and even more preferably from 10⁻² g/m²·d to 10⁻⁴ g/m²·d. Note that, the water-vapor permeability can be measured in accordance with JIS Z0208 or the like.

For the formation of a barrier layer, a dry method as described below is preferably used.

—Method of Forming Barrier Layer—

Examples of a method of forming a gas barrier layer in accordance with a dry process include a vacuum deposition method such as resistance heating vapor deposition, electron beam vapor deposition, induction heating vapor deposition, or a plasma or ion beam-assisted method of the above vapor deposition; a sputtering method such as a reactive sputtering method, an ion beam sputtering method, or an ECR (electron cyclotron resonance) sputtering method; a physical vapor phase growth method (PVD method) such as ion plating method; and a chemical vapor phase growth method (CVD method) utilizing heat, light, plasma, or the like. Among them, a vacuum deposition method wherein a film is formed by a vapor deposition method under vacuum is preferable.

Here, in a case in which the gas barrier layer is an inorganic layer that is formed by a material containing, as the main constituent component, an inorganic oxide, an inorganic nitride, an inorganic oxynitride, an inorganic halide, an inorganic sulfide, or the like, it is also possible to directly volatize the same material as the composition of the gas barrier layer to be formed and deposit the material on the base material or the like. However, when carrying out this method, the composition may change during vaporization and, as a result, there are cases in which the formed film does not exhibit uniform properties. For that reason, 1) a method of using, as the vaporization source, a material having the same composition as that of the barrier layer to be formed, and carrying out vaporization, while auxiliary introducing, for example, oxygen gas in the case of an inorganic oxide, nitrogen gas in the case of an inorganic nitride, a mixed gas of oxygen gas and nitrogen gas in the case of an inorganic oxynitride, a halogen-based gas in the case of an inorganic halide, or a sulfur-based gas in the case of an inorganic sulfide, into the system; 2) a method of using an inorganic matter group as the vaporization source and, while vaporizing this, introducing, for example, oxygen gas in the case of an inorganic oxide, nitrogen gas in the case of an inorganic nitride, a mixed gas of oxygen gas and nitrogen gas in the case of an inorganic oxynitride, a halogen-based gas in the case of an inorganic halide, or a sulfur-based gas in the case of an inorganic sulfide, into the system, and then carrying out deposition onto the surface of the base material, while allowing the inorganic matter to react with the introduced gas; 3) a method of using an inorganic matter group as the vaporization source, vaporizing this and thereby forming a layer of the inorganic matter group, and thereafter maintaining the formed layer, for example, under an oxygen gas atmosphere in the case of an inorganic oxide, under a nitrogen gas atmosphere in the case of an inorganic nitride, under an atmosphere of a mixed gas of oxygen gas and nitrogen gas in the case of an inorganic oxynitride, under a halogen-based gas atmosphere in the case of an inorganic halide, or under a sulfur-based gas atmosphere in the case of an inorganic sulfide, to thereby allow the inorganic matter layer to react with the introduced gas; and the like are described.

Among them, from the viewpoint of ease of vaporization from the vaporization source, the method of 2) or 3) is used more preferably. Further, from the viewpoint of ease of control of film properties, the method of 2) is used even more preferably. Moreover, in a case in which the barrier layer is an inorganic oxide, a method of using an inorganic matter group as the vaporization source, vaporizing this and thereby forming a layer of the inorganic matter group, and thereafter allowing to stand the formed layer in the air, to thereby naturally oxidize the inorganic matter group is also preferable from the viewpoint of ease of formation.

Further, it is also preferable to paste an aluminum foil and use the aluminum foil as a barrier layer. The thickness is preferably from 1 μm to 30 μm. When the thickness of the barrier layer is 1 μm or more, water hardly penetrates into the polyester base material during aging (thermal aging) and thus, hydrolysis is less likely to occur. When the thickness is 30 μm or less, the thickness of the barrier layer does not become too thick, and thus, kink does not occur in the base material due to the stress of the barrier layer.

<Solar Cell Module>

The solar cell module of the present invention is constituted by providing the above-described backsheet for a solar cell of the invention, or a backsheet for a solar cell produced by the above-described method of producing a backsheet for a solar cell. In a preferable embodiment of the present invention, the solar cell module is constituted such that a solar cell element that converts the light energy of sunlight to electrical energy is disposed between a transparent front base board, through which sunlight enters, and the above-described backsheet for a solar cell of the invention, and the solar cell element is sealed and adhered between the front base board and the backsheet, using a sealing material such as an ethylene-vinyl acetate sealing material. That is, a cell structural portion having a solar cell element and a sealing material that seals the solar cell element is provided between the front base board and the backsheet.

Regarding members other than the solar cell module, the photovoltaic cells, and the backsheet, they are described in detail in “Taiyoko Hatsuden System Kosei Zairyo” (under the supervision of Eiichi Sugimoto, published by Kogyo Chosakai Publishing, Inc., 2008), for example.

The transparent base board may only has a light transparency to such an extent that sunlight is allowed to pass through it, and may be selected appropriately from base materials that allow light to transmit therethrough. From the viewpoint of power generation efficiency, a transparent base board that has a higher light transmittance is more preferable. For such a transparent base board, a glass base board, a transparent resin such as acrylic resin and the like may be suitably used, for example.

For the solar cell elements, various kinds of known solar cell elements may be used, including: solar cells based on silicon such as single crystal silicon, polycrystalline silicon, or amorphous silicon; and solar cells based on a III-V or II-VI compound semiconductor such as copper-indium-gallium-selenium, copper-indium-selenium, cadmium-tellurium, or gallium-arsenic.

### EXAMPLES

The present invention will be further described in detail with reference to the following examples, but it should be construed that the present invention is in no way limited to those examples as long as not departing from the scope of the invention. Note that, “part(s)” and “%” in Examples are on the basis of mass.

<Production of Polyester Base Material>

—Production of PET-1—

[Step 1]

100 parts of dimethyl terephthalate, trimethyl trimellitate (added to achieve a molar ratio of dimethyl terephthalate/trimethyl trimellitate=99.7/0.3), 57.5 parts of ethylene glycol, 0.06 parts of magnesium acetate, and 0.03 parts of antimony trioxide were melted at 150° C. in a nitrogen atmosphere, and while the mixture was stirred, the temperature was increased to 230° C. over 3 hours. Methanol was distilled off, and thus a transesterification reaction was completed.

[Step 2]

After completion of the transesterification reaction, an ethylene glycol solution prepared by dissolving 0.019 parts (equivalent to 1.9 mol/t) of phosphoric acid and 0.027 parts (equivalent to 1.5 mol/t) of sodium dihydrogen phosphate dihydrate in 0.5 parts of ethylene glycol, was added to the system.

[Step 3]

A polymerization reaction was carried out at an end-point temperature of 285° C. and a degree of vacuum of 0.1 Torr, and thus a polyester having an intrinsic viscosity of 0.54 and a number of terminal carboxyl groups of 13 eq/ton was obtained.

[Step 4]

The polyethylene terephthalate thus obtained was dried for 6 hours at 160° C. and was crystallized. Subsequently, solid phase polymerization was carried out at 220° C. and at a degree of vacuum of 0.3 Ton for 9 hours, and thus a polyester having 0.15% by mole of the constituent component (p), an intrinsic viscosity of 0.90, a number of terminal carboxyl groups of 12 eq/ton, a melting point of 255° C., and a glass transition temperature Tg of 83° C. was obtained.

[Step 5]

One part of a polycarbodiimide (trade name: STABAXOL P100″, manufactured by Rhein Chemie Rheinau GmbH) was added to 99 parts of the polyester obtained in Step 4, and the mixture was compounded.

[Step 6]

The compounded product obtained as described above was subjected to drying under reduced pressure for 2 hours under the conditions of a temperature of 180° C. and a degree of vacuum of 0.5 mmHg, and the dried product was supplied to an extruder which had been heated to 295° C. Foreign materials were filtered using a 50-μm cutoff filter, and then the compounded product was introduced into a T-die nozzle. Subsequently, the compounded product was extruded through the T-die nozzle into a sheet form, and thus a molten single-layer sheet was obtained. The molten single-layer sheet was adhered onto a drum which had been maintained at a surface temperature of 20° C., by an electrostatic application method, and the molten single-layer sheet was cooled and solidified. Thus, an unstretched single layer film was obtained.

[Step 7]

Subsequently, the unstretched single-layer film thus obtained was preheated using a group of heated rolls, and then MD stretching 1 was carried out to 1.8 times at a temperature of 80° C., followed by MD stretching 2 to 2.3 times at a temperature of 95° C. Stretching was carried out to 4.1 times in total in the longitudinal direction (MD), and then the film was cooled with a group of rolls at a temperature of 25° C. Thus, a uniaxially stretched film was obtained. While two edges of the uniaxially stretched film thus obtained were clamped with clips, the uniaxially stretched film was led into a preheating zone at a temperature of 95° C. in a tenter, and subsequently, the film was continuously stretched to 4.0 times in the width direction (TD), which was perpendicular to the longitudinal direction, in a heating zone at a temperature of 100° C.

[Step 8]

Subsequently, the film was subjected to a heat treatment for 20 seconds at a temperature of 205° C. (first heat treatment temperature) in a heat treatment zone in the tenter. Subsequently, the film was relaxed at a relaxation ratio of 3% in the width direction (TD) at a temperature of 180° C., and by reducing the clip interval of the tenter, the film was relaxed at a relaxation ratio of 1.5% in the longitudinal direction (MD). Subsequently, the film was uniformly cooled to 25° C., and then was rolled. Thus, a biaxially stretched polyester film (PET-1) having a thickness of 250 μm was obtained.

Note that, the relaxation ratio can be calculated according to the following Formula (c), when designating the length of the polyester film before relaxation as La, and designating the length of the polyester film after relaxation as Lb.

100×(La−Lb)/La Formula (c)

La and Lb in the width direction of the polyester film, and La and Lb in the longitudinal direction of the polyester film are defined as described below.

[Width Direction]

When a polyester film is stretched by applying tension using a tenter, the maximum width of the polyester film at the time of stretching is designated as the length of the polyester film before relaxation La. Further, the width of the polyester film after releasing the tension (relaxing) and taking the polyester film out from the tenter is designated as the length of the polyester film after relaxation Lb.

[Longitudinal Direction]

When a polyester film is stretched by applying tension using a tenter, the polyester film at the time of stretching is marked at two points in the longitudinal direction, and the distance between the two points is designated as the length of the polyester film before relaxation La. Further, the distance between the two points after releasing the tension (relaxing) and taking the polyester film out from the tenter is designated as the length of the polyester film after relaxation Lb.

The results of an evaluation of the characteristics of PET-1 are presented below.
Content of terminal carboxyl groups: 5 eq/t
Tmeta: 190° C.
Average elongation retention ratio: 50%
Plane orientation coefficient: 0.170
Intrinsic viscosity: 0.75 dL/g
Thermal shrinkage ratio (MD/TD): 0.4%/0.2%
Content of constituent component (p): 0.15 mol %
Buffering agent: Sodium dihydrogen phosphate 1.5 mol/t
Terminal blocking agent: Polycarbodiimide 1 wt %
Content of phosphorus atoms: 230 ppm.

—Production of PET-2—

Production of a biaxially stretched polyester film (PET-2) was conducted in a manner substantially similar to that in the production of PET-1, except that the first heat treatment temperature in [Step 8] in the production method of PET-1 was changed to 230° C.

The characteristics of PET-2 were evaluated, and it was revealed that, as compared with PET-1, Tmeta was changed to 225° C., and the average elongation retention ratio was changed to 7%.

—Production of PET-3—

Production of a biaxially stretched polyester film (PET-3) was conducted in a manner substantially similar to that in the production of PET-1, except that, in [Step 2] in the production method of PET-1, sodium dihydrogen phosphate dihydrate was not added.

The characteristics of PET-3 were evaluated, and it was revealed that, as compared with PET-1, the average elongation retention ratio was changed to 40%, and the content of phosphorus atom was changed to 150 ppm.

The characteristics of PET-1 were measured according to the following methods.

—Carboxyl Group Content (AV)—

The polyester was thoroughly dissolved in a mixed solution of benzyl alcohol/chloroform (=2/3:volume ratio), and the solution was titrated against a standard solution (0.01N KOH-benzyl alcohol mixed solution), using phenol red as an indicator. The carboxyl group content (AV) was calculated from the titer.

—Minute Endothermic Peak Temperature Tmeta (° C.) Determined by Differential Scanning Calorimetry (DSC)—

The minute endothermic peak temperature Tmeta (° C.) was measured using a differential scanning calorimetric apparatus “ROBOT DSC-RDC220” (trade name, manufactured by Seiko Instruments and Electronics Co., Ltd.) in accordance with JIS K7122-1987 (by reference to JIS Handbook, 1999 edition), and the data analysis was conducted using a disc session “SSC/5200” (trade name). Specifically, 5 mg of the film were weighed and set in a sample pan, and measurement was conducted while raising the temperature from 25° C. to 300° C. at a temperature increase rate of 20° C./min.

The temperature of a minute endothermic peak appearing before the crystalline melting peak in the differential scanning calorimetric chart thus obtained is designated as Tmeta (° C.). In a case in which a minute endothermic peak was hardly observed, the vicinity of the peak was magnified at the data analysis unit, and the peak was read out.

The method for reading the graph of a minute endothermic peak is not described in JIS; however, graph reading was carried out according to the following method.

First, a straight line was drawn between the value at 135° C. and the value at 155° C., and the area between the straight line and the graph curve on the endotherm side was determined. Similarly, the areas at 17 pairs of points of 140° C. and 160° C., 145° C. and 165° C., 150° C. and 170° C., 155° C. and 175° C., 160° C. and 180° C., 165° C. and 185° C., 170° C. and 190° C., 175° C. and 195° C., 180° C. and 200° C., 185° C. and 205° C., 190° C. and 210° C., 195° C. and 215° C., 200° C. and 220° C., 205° C. and 225° C., 210° C. and 230° C., 215° C. and 235° C., and 220° C. and 240° C. were determined. Since the amount of heat absorption of a minute peak is generally from 0.2 J/g to 5.0 J/g, only the data in which the area was within the range of from 0.2 J/g to 5.0 J/g were employed as effective data. Among the 18 area data in total, the peak temperature of an endothermic peak which is in a temperature region of a datum that shows the largest area and is an effective datum is designated as Tmeta (° C.). In a case in which there are not any effective data, it is determined that Tmeta (° C.) is absent.

—Average Elongation Retention Ratio—

Measurement of breaking elongation was carried out according to ASTM-D882-97 (by reference to ANNUAL BOOK OF ASTM STANDARDS, 1999 edition). A sample was cut to a size of 1 cm×20 cm, and the breaking elongation (initial) was measured by pulling the sample under the conditions of a distance between chucks of 5 cm and a rate of pulling of 300 mm/min. The measurement was carried out for 5 samples, and the average value is designated as breaking elongation (initial) A2.

Subsequently, a sample was cut to a size of 1 cm×20 cm, and the sample was treated under the conditions of a temperature of 125° C. and a humidity of 100% for 72 hours using a highly accelerated life testing apparatus (HAST apparatus), PC-304R8D (trade name, manufactured by Hirayama Manufacturing Corp.). Thereafter, the breaking elongation (after treatment) of the sample that had been treated was measured by pulling the sample under the conditions of a distance between chucks of 5 cm and a rate of pulling of 300 mm/min, according to ASTM-D882 (1999)-97 (by reference to ANNUAL BOOK OF ASTM STANDARDS, 1999 edition). The measurement was carried out for 5 samples, and the average value is designated as breaking elongation (after treatment) A3.

Using the breaking elongations A2 and A3 thus obtained, the elongation retention ratio (Lr) was calculated according to the following Equation (3).

Lr(%)=A3/A2×100 (3)

Further, the average elongation retention ratio (Lave) was calculated according to the following Equation (4).

(Lave)(%)=(LrMD+LrTD)/2 (4)

Here, LrMD represents the elongation retention ratio in the MD direction and LrTD represents the elongation retention ratio in the TD direction.

—Plane Orientation Coefficient (f_{PO})—

The film refractive index was measured using an Abbe refractometer TYPE 4T (trade name, manufactured by Atago Co., Ltd.) and using a sodium lamp as the light source.

f_{PO}=(nMD+nTD)/2−nZD (A)

In Equation (A) above, nMD represents the refractive index in the longitudinal direction (MD) of the film; nTD represents the refractive index in the orthogonal direction (TD) of the film; and nZD represents the refractive index in the film thickness direction.

—Intrinsic Viscosity (IV)—

The intrinsic viscosity (IV) is a value obtained by extrapolating the value obtained by dividing the specific viscosity (ηₛₚ=ηᵣ−1), which is obtained by subtracting 1 from the ratio ηᵣ (=η/η₀; relative viscosity) of the solution viscosity (η) to the solvent viscosity (η₀), by the concentration, to zero concentration. IV is determined from the solution viscosity at 25° C., using a Ubbelohde viscometer, and dissolving the polyester in a mixed solvent of 1,1,2,2-tetrachloroethane/phenol (=2/3 [mass ratio]).

—Thermal Shrinkage Ratio (MD/TD)—

A sample having a width of 10 mm and a distance between marked lines of about 100 mm was heat treated, according to JIS-C2318 (2007), at a temperature of 150° C. and under a load of 0.5 g for 30 minutes. The distance between the marked lines was measured before and after the heat treatment, using a thermal shrinkage ratio measuring device (trade name: No. AMM-1 machine, manufactured by Techno Needs Co., Ltd.), and the thermal shrinkage ratio was calculated according to the following Equation.

Rts(%)={(L₀−L)/L₀}×100

Rts: Thermal shrinkage ratio

L₀: Distance between marked lines before heat treatment

L: Distance between marked lines after heat treatment

—Content of Phosphorus Atoms—

The content of phosphorus atoms was measured by a fluorescent X-ray method (trade name: ZSX 100E, manufactured by Rigaku Corp.)

[Surface Treatment]

One of the surfaces of the support of each of PET-1 to PET-3 thus obtained was subjected to a corona treatment under the following conditions.

Apparatus: Solid state corona treatment apparatus 6 KVA MODEL (trade name, manufactured by Pillar Technologies)

Gap clearance between electrode and dielectric roll: 1.6 mm

Treatment frequency: 9.6 kHz

Treatment speed: 20 m/min

Treatment intensity: 0.375 kV·A·min/m²

The carboxyl group content (AV), Tmeta, the average elongation retention ratio, and the kind of surface treatment of each of the obtained PET-1 to PET-3 are shown in Table 1.

TABLE 1

| | Support configuration | | | |
|---|---|---|---|---|
| | | | Average elongation | |
| | AV | Tmeta | retention ratio | Surface treatment |
| | (eq/t) | (° C.) | (%) | (Kind) |
| PET-1 | 5 | 190 | 50 | corona |
| PET-2 | 5 | 225 | 7 | corona |
| PET-3 | 5 | 190 | 40 | corona |

<Production of Polymer Sheet>

Using PET-1 or PET-2 shown in Table 1 as the support, a polymer sheet having a polymer layer (polymer 1, or polymer 1 and polymer 2) with a configuration shown in Table 2 on the corona-treated surface was produced. In the case of forming polymer layer 2, polymer layer 1 was formed on the support, and then polymer layer 2 was formed on the polymer layer 1.

Note that, in the polymer sheet, the surface at which a polymer layer (polymer layer 1, or polymer layer 1 and polymer layer 2) is formed is referred to as the front face of the polymer sheet. Further, the surface of the polymer sheet opposite from the front face is referred to as the rear face of the polymer sheet.

In the support (PET-1 to PET-3), the surface at which polymer layer 1, or polymer layer 1 and polymer layer 2 is (are) formed is referred to as the front face of the support. Further, the surface of the support opposite from the front face is referred to as the rear face of the support.

For the formation of polymer layer 1 and polymer layer 2, the following binders P-1 to P-5 were used.

P-1: CERANATE WSA-1070 (acryl/silicone-based binder)

[trade name, manufactured by DIC Corp.; silicone binder, solids content: 40% by mass]

P-2: CERANATE WSA-1060 (acryl/silicone-based binder)

[trade name, manufactured by DIC Corp.; silicone binder, solids content: 40% by mass]

P-3: OBBLIGATO SW0011F

[trade name, manufactured by AGC Coat-Tech Co., Ltd.; fluoro resin, solids content: 40% by mass]

P-4: FINETEX ES650

[trade name, manufactured by DIC Corp.; polyester resin, solids content: 29% by mass]

P-5: OLESTER UD350

[trade name, manufactured by Mitsui Chemicals, Inc.; polyurethane resin, solids content: 38% by mass]

Here, the molecular constitutions of P-1 and P-2, each of which is a silicone resin (composite polymer), are as follows.

P-1 contains about 30% by mass of a polysiloxane moiety and about 70% by mass of an acrylic polymer moiety.

P-2 contains about 75% by mass of a polysiloxane moiety and about 25% by mass of an acrylic polymer moiety.

### Example 1

### Preparation of Pigment Dispersion

Various components of the following composition were mixed, and the mixture was subjected to a dispersion treatment for one hour using a Dyno Mill type dispersing machine.

(Composition of Pigment Dispersion)

| | |
|---|---|
| Titanium dioxide (volume average particle size = 0.42 μm) | 40 mass % |
| (trade name: TIPAQUE R-780-2, manufactured by | |
| Ishihara Sangyo Kaisha, Ltd.; solids content 100% by mass) | |
| Aqueous solution of polyvinyl alcohol (10 mass %) | 20.0 mass % |
| (trade name: PVA-105, manufactured by Kuraray Co., Ltd.) | |
| Surfactant | 0.5 mass % |
| (trade name: DEMOL EP, manufactured by Kao Corp.; | |
| solids content: 25% by mass) | |
| Distilled water | 39.5 mass % |

### Preparation of Coating Liquid for Forming Polymer Layer-1

Various components of the following composition were mixed, and thus a coating liquid 1-P1 for forming polymer layer-1 was prepared.

(Composition of Coating Liquid)

| | |
|---|---|
| Binder (P-1) | 362.3 parts |
| (trade name: CERANATE WSA-1070, | |
| manufactured by DIC Corp., solids content: | |
| 40% by mass) | |
| Carbodiimide compound (crosslinking agent) | 36.2 parts |
| (trade name: CARBODILITE V-02-L2, | |
| manufactured by Nisshinbo Holdings, Inc.; | |
| solids content: 40% by mass) | |
| Surfactant | 9.7 parts |
| (trade name: NAROACTY CL95, | |
| manufactured by Sanyo Chemical Industries, | |
| Ltd.; solids content: 1% by mass) | |
| Dispersion described above | 157.0 parts |
| Distilled water | 434.8 parts |

—Formation of Polymer Layer 1—

The coating liquid 1-P 1 for forming polymer layer 1 thus obtained was applied on the corona-treated surface of the support, such that the amount of binder in terms of the amount of application was 3.0 g/m², and the coating liquid was dried for one minute at 180° C. Thus, polymer layer 1 having a dry thickness of about 5 μm was formed.

In this way, polymer sheet 1 of Example 1 was produced.

<Evaluation>

1. Adhesiveness

(A) Adhesiveness Before a Lapse of Time Under Moisture and Heat

The polymer sheet produced as described above was cut to a size of 20 mm in width×150 mm, and thus two sheets of sample strips were prepared. These two sheets of sample strips were arranged such that each of the polymer layer side of each strip would face each other at inside, and an EVA sheet (EVA sheet manufactured by Mitsui Chemicals Fabro, Inc.: SC50B, trade name) which had been previously cut to a size of 20 mm in width×100 mm in length was interposed between the two sheets. The two sheets of sample strips were adhered to the EVA by hot pressing the assembly using a vacuum laminator (vacuum laminating machine manufactured by Nisshinbo Holdings, Inc.). The conditions for adhesion at this time were as shown below.

The assembly was subjected to a vacuum at 128° C. for 3 minutes using a vacuum laminator, and thus provisional adhesion was achieved by pressing for 2 minutes. Thereafter, the assembly was subjected to a main adhesion treatment in a dry oven at 150° C. for 30 minutes. As such, there was obtained a sample for adhesion evaluation having an area of 20 mm from one edge of the two sheets of sample strips adhered to each other remaining unadhered to EVA, and having the remaining area of 100 mm adhered to the EVA sheet.

The EVA-unadhered area of the obtained sample for adhesion evaluation was clamped between upper and lower clips in a TENSILON (RTC-1210A, trade name, manufactured by Orientec Co., Ltd.), and a test was performed by drawing at a peeling angle of 180° and a rate of pulling of 300 mm/min. Thus the adhesive power was measured.

The adhesive power thus measured was used to grade the samples according to the following evaluation criteria. Among these, grades 4 and 5 fall in the practically acceptable range.

<Evaluation Criteria>

5: The adhesion was very good (60 N/20 mm or greater)

4: The adhesion was good (from 30 N/20 mm to less than 60 N/20 mm)

3: The adhesion was slightly poor (from 20 N/20 mm to less than 30 N/20 mm)

2: Adhesion failure occurred (from 10 N/20 mm to less than 20 N/20 mm)

1: Adhesion failure was noticeable (less than 10 N/20 mm)

[B] Adhesiveness after a Lapse of Time Under Moisture and Heat

The sample for adhesion evaluation thus obtained was stored (subjected to wet heat aging) for 48 hours under environmental conditions of 120° C. and 100% RH, and thereafter, the adhesive power was measured by the same method as the method used in [A] above. With regard to the adhesive power after the storage thus measured, a ratio [%;=adhesive power after a lapse of time under moisture and heat/[A] adhesive power before a lapse of time under moisture and heat×100] thereof relative to the [A] adhesive power before a lapse of time under moisture and heat of the same sample for adhesion evaluation was calculated. Further, based on the adhesive power after a lapse of time under moisture and heat thus measured, the adhesive power was evaluated according to the same method as the method used in [A] above.

—2. Durability—

The polymer sheet thus produced was stored for 50 hours under an atmosphere of 120° C. and 100% RH, and thereafter, the surface of the front face (the surface of a side having thereon the polymer layer) of the polymer sheet was observed visually and with an optical microscope (trade name ME-600, manufactured by Nikon Corporation; magnification: ×100). The results were ranked as follows.

Evaluation grades 4 and 5 fall in the practically acceptable range.

<Evaluation Criteria>

5: No change is recognized at the surface even when observed with an optical microscope.

4: Slight cracks or deformations are seen at the surface, when observed with an optical microscope.

3: It is understood that the glossiness on the surface is lost, when observed visually.

2: Slight cracks are seen, when observed visually.

1: Cracks are seen over the entire surface even when observed visually.

### Example 2 to Example 4

Polymer sheet 2 to polymer sheet 4 of Example 2 to Example 4 were produced in a manner substantially similar to that in Example 1, except that the coating liquid 1-P1 for forming polymer layer 1 in the formation of polymer layer 1 in Example 1 was applied such that the thickness of polymer layer 1 was the thickness shown in Table 2. The polymer sheet 2 to polymer sheet 4 thus obtained were evaluated in a manner substantially similar to that in polymer sheet 1. Results are shown in Table 2.

### Example 5

Polymer sheet 5 of Example 5 was produced in a manner substantially similar to that in Example 1, except that the coating liquid 1-P1 for forming polymer layer 1 in the production of the polymer sheet 1 in Example 1 was changed to coating liquid 1-P2 for forming polymer layer 1. The polymer sheet 5 thus obtained was evaluated in a manner substantially similar to that in polymer sheet 1. Results are shown in Table 2.

Note that, preparation of coating liquid 1-P2 for forming polymer layer 1 was conducted in a manner substantially similar to that in the preparation of coating liquid 1-P1 for forming polymer layer 1, except that the binder (P-1) was changed to binder (P-2).

### Example 6

The coating liquid for forming polymer layer 2 described below was further applied on the polymer layer 1 of polymer sheet 3 of Example 3, thereby forming polymer layer 2. In this way, polymer sheet 6 of Example 6 was produced. The polymer sheet 6 thus obtained was evaluated in a manner substantially similar to that in polymer sheet 1. Results are shown in Table 2.

### Preparation of Coating Liquid for Forming Polymer Layer-2

Various components of the following composition were mixed, and thus a coating liquid 2-P1 for forming polymer layer-2 was prepared.

(Composition of Coating Liquid)

| | |
|---|---|
| Binder (P-1) | 362.3 parts |
| (trade name: CERANATE WSA-1070, | |
| manufactured by DIC Corp.; solids content: | |
| 40% by mass) | |
| Carbodiimide compound (crosslinking agent) | 24.2 parts |
| (trade name: CARBODILITE V-02-L2, | |
| manufactured by Nisshinbo Holdings, Inc.; | |
| solids content: 40% by mass) | |
| Surfactant | 24.2 parts |
| (trade name: NAROACTY CL95, | |
| manufactured by Sanyo Chemical Industries, | |
| Ltd.; solids content: 1% by mass) | |
| Distilled water | 703.8 parts |

—Formation of Polymer Layer-2—

The coating liquid 2-P1 for forming polymer layer-2 thus obtained was applied on the polymer layer-1 of polymer sheet 3, such that the amount of binder in terms of the amount of application was 2.0 g/m², and the coating liquid was dried for one minute at 180° C. Thus, polymer layer-2 having a dry thickness of about 2 μm was formed.

### Example 7 and Example 8

Polymer sheet 7 and polymer sheet 8 of Example 7 and Example 8 were produced in a manner substantially similar to that in Example 6, except that the coating liquid 2-P1 for forming polymer layer 2 in the formation of polymer layer 2 in Example 6 was applied such that the thickness of polymer layer 2 was the thickness shown in Table 2. The polymer sheet 7 and polymer sheet 8 thus obtained were evaluated in a manner substantially similar to that in polymer sheet 1. Results are shown in Table 2.

### Example 9

Polymer sheet 9 of Example 9 was produced in a manner substantially similar to that in Example 6, except that the coating liquid 2-P1 for forming polymer layer 2 in the production of polymer sheet 6 in Example 6 was changed to coating liquid 2-P2 for forming polymer layer 2. The polymer sheet 9 thus obtained was evaluated in a manner substantially similar to that in polymer sheet 1. Results are shown in Table 2.

Note that, preparation of coating liquid 2-P2 for forming polymer layer 2 was conducted in a manner substantially similar to that in the preparation of coating liquid 2-P1 for forming polymer layer 2, except that the binder (P-1) was changed to binder (P-2).

### Example 10

Polymer sheet 10 of Example 10 was produced in a manner substantially similar to that in Example 6, except that the coating liquid 2-P1 for forming polymer layer 2 in the production of polymer sheet 6 in Example 6 was changed to coating liquid 2-P3 for forming polymer layer 2. The polymer sheet 10 thus obtained was evaluated in a manner substantially similar to that in polymer sheet 1. Results are shown in Table 2.

Note that, preparation of coating liquid 2-P3 for forming polymer layer 2 was conducted in a manner substantially similar to that in the preparation of coating liquid 2-P1 for forming polymer layer 2, except that the binder (P-1) was changed to binder (P-3).

### Example 11 and Example 12

Polymer sheet 11 and polymer sheet 12 of Example 11 and Example 12 were produced in a manner substantially similar to that in Example 10, except that the coating liquid 2-P3 for forming polymer layer 2 in the formation of polymer layer 2 in Example 10 was applied such that the thickness of polymer layer 2 was the thickness shown in Table 2. The polymer sheet 11 and polymer sheet 12 thus obtained were evaluated in a manner substantially similar to that in polymer sheet 1. Results are shown in Table 2.

### Comparative Example 1

Polymer sheet 101 of Comparative Example 1 was produced in a manner substantially similar to that in Example 1, except that the coating liquid 1-P1 for forming polymer layer 1 in the production of polymer sheet 1 in Example 1 was changed to coating liquid 1-P4 for forming polymer layer 1. The polymer sheet 101 thus obtained was evaluated in a manner substantially similar to that in polymer sheet 1. Results are shown in Table 2.

Note that, preparation of coating liquid 1-P4 for forming polymer layer 1 was conducted in a manner substantially similar to that in the preparation of coating liquid 1-P1 for forming polymer layer 1, except that the binder (P-1) was changed to binder (P-4).

### Comparative Example 2

Polymer sheet 102 of Comparative Example 2 was produced in a manner substantially similar to that in Example 1, except that the coating liquid 1-P1 for forming polymer layer 1 in the production of polymer sheet 1 in Example 1 was changed to coating liquid 1-P5 for forming polymer layer 1. The polymer sheet 102 thus obtained was evaluated in a manner substantially similar to that in polymer sheet 1. Results are shown in Table 2.

Note that, preparation of coating liquid 1-P5 for forming polymer layer 1 was conducted in a manner substantially similar to that in the preparation of coating liquid 1-P1 for forming polymer layer 1, except that the binder (P-1) was changed to binder (P-5).

### Comparative Example 3

Polymer sheet 103 of Comparative Example 3 was produced in a manner substantially similar to that in Example 1, except that the support PET-1 in the production of polymer sheet 1 in Example 1 was changed to PET-2. The polymer sheet 103 thus obtained was evaluated in a manner substantially similar to that in polymer sheet 1. Results are shown in Table 2.

### Example 13 to Example 15, and Comparative Example 4 and Comparative Example 5

Polymer sheets 13 to 15 of Example 13 to Example 15, and polymer sheets 104 and 105 of Comparative Example 4 and Comparative Example 5 were produced in a manner substantially similar to that in the production of polymer sheet 7 in Example 7, except that the type of binder of polymer layer 1 was changed to one of PS-1 to PS-5 as shown in Table 2.

The polymer sheets 13 to 15, and 104 and 105 thus obtained were evaluated in a manner substantially similar to that in polymer sheet 1. However, with regard to the system (Comparative Example 5) using PS-5 as the binder, evaluation could not be carried out since the stability was not good. Results are shown in Table 2.

The binders PS-1 to PS-5 used in Example 13 to Example 15, and Comparative Example 4 and Comparative Example 5 were synthesized as follows. Note that, in Synthesis Example-1 to Synthesis Example-5, “%” is on the basis of mass, unless otherwise specifically stated.

### Synthesis Example-1

In a reaction vessel equipped with a stirring device and a dropping funnel and substituted with nitrogen gas, 81 parts of propylene glycol mono-n-propyl ether (PNP), 360 parts of isopropyl alcohol (IPA), 110 parts of phenyltrimethoxysilane (PTMS), and 71 parts of dimethyldimethoxysilane (DMDMS) were placed, and while stirring the mixture under a nitrogen gas atmosphere, the temperature was raised to 60° C.

Subsequently, at the same temperature, a mixture including 260 parts of methyl methacrylate (MMA), 200 parts of n-butyl methacrylate (BMA), 110 parts of n-butyl acrylate (BA), 30 parts of acrylic acid (AA), 19 parts of 3-methacryloyloxy propyl trimethoxysilane (MPTMS), 31.5 parts of tert-butyl peroxy-2-ethyl hexanoate (TBPO) and 31.5 parts of PNP was added thereto dropwise over 4 hours.

Thereafter, the resulting mixture was heated and stirred at the same temperature for 2.5 hours, and thus a solution of an acrylic polymer having a weight average molecular weight of about 30000 and containing a carboxyl group and a hydrolyzable silyl group was obtained.

Subsequently, 54.8 parts of deionized water was added to the mixture, and the mixture was continuously heated and stirred for 16 hours, to hydrolyze the alkoxysilane and undergo condensation with the acrylic polymer, whereby a solution of a composite polymer having a non-volatile component (NV) of 56% and a solution acid value of 22 mgKOH/g, and having a carboxyl group-containing acrylic polymer moiety and a polysiloxane moiety was obtained.

Subsequently, while stirring at the same temperature, 42 parts of triethylamine were added thereto and the mixture was stirred for 10 minutes. Thereby, 100% of the carboxyl groups contained were neutralized.

Thereafter, at the same temperature, 1250.0 parts of deionized water were added thereto dropwise over 1.5 hrs. to undergo phase inversion emulsification, and then the temperature was lowered to 50° C. and the mixture was stirred for 30 minutes. Subsequently, at an internal temperature of 40° C., a portion of water was removed together with the organic solvent under reduced pressure over 3.5 hours. In this way, a water dispersion (PS-1) of a composite polymer having a solids concentration of 42% and an average particle diameter of 110 nm, and having a carboxyl group-containing acrylic polymer moiety and a polysiloxane moiety was obtained. The content of the polysiloxane moiety in PS-1 is about 25%.

### Synthesis Example-2

PS-2 was synthesized in a manner substantially similar to that in Synthesis Example-1, except that the amounts of monomers used were changed as follows.

Phenyltrimethoxysilane (PTMS): 210 parts; dimethyldimethoxysilane (DMDMS): 166 parts; 3-methacryloyloxy propyl trimethoxysilane (MPTMS): 24 parts; methyl methacrylate (MMA): 200 parts; n-butyl methacrylate (BMA): 100 parts; n-butyl acrylate (BA): 70 parts; and acrylic acid (AA): 30 parts. The content of the polysiloxane moiety in PS-2 is about 50%.

### Synthesis Example-3

PS-3 was synthesized in a manner substantially similar to that in Synthesis Example-1, except that the amounts of monomers used were changed as follows.

Phenyltrimethoxysilane (PTMS): 320 parts; dimethyldimethoxysilane (DMDMS): 244 parts; 3-methacryloyloxy propyl trimethoxysilane (MPTMS): 36 parts; methyl methacrylate (MMA): 90 parts; n-butyl methacrylate (BMA): 60 parts; n-butyl acrylate (BA): 20 parts; and acrylic acid (AA): 30 parts. The content of the polysiloxane moiety in PS-3 is about 75%.

### Synthesis Example-4

PS-4 was synthesized in a manner substantially similar to that in Synthesis Example-1, except that the amounts of monomers used were changed as follows.

Phenyltrimethoxysilane (PTMS): 60 parts; dimethyldimethoxysilane (DMDMS): 25 parts; 3-methacryloyloxy propyl trimethoxysilane (MPTMS): 15 parts; methyl methacrylate

(MMA): 300 parts; n-butyl methacrylate (BMA): 220 parts; n-butyl acrylate (BA): 150 parts; and acrylic acid (AA): 30 parts. PS-4 is a polymer containing about 13% of the polysiloxane moiety, and is not classified as the composite polymer according to the present invention.

### Synthesis Example-5

PS-5 was synthesized in a manner substantially similar to that in Synthesis Example-1, except that the amounts of monomers used were changed as follows.

Phenyltrimethoxysilane (PTMS): 360 parts; dimethyldimethoxysilane (DMDMS): 320 parts; 3-methacryloyloxy propyl trimethoxysilane (MPTMS): 40 parts; methyl methacrylate (MMA): 20 parts; n-butyl methacrylate (BMA): 20 parts; n-butyl acrylate (BA): 10 parts; and acrylic acid (AA): 30 parts. PS-5 is a polymer containing about 90% of the polysiloxane moiety, and is not classified as the composite polymer according to the present invention. Further, aggregation occurred in this water dispersion of polymer, and the stability was not good.

TABLE 2

| | | | | | | | | | | | Performance Evaluation | | |
|---|---|---|---|---|---|---|---|---|---|---|---|---|---|
| | Support | | | | Polymer Layer 1 | | | Polymer Layer 2 | | | 1 Adhesiveness | | |
| | | AV | Tmeta | AERR | Binder | | Thick | Binder | | Thick | LTMH | | |
| | Kind | [eq/t] | % | [%] | Kind | Resin type | [μm] | Kind | Resin type | [μm] | Before | After | 2 Durability |
| Exp. 1 | PET-1 | 5 | 190 | 50 | P-1 | Silicone | 5 | — | — | — | 5 | 5 | 5 |
| Exp. 2 | PET-1 | 5 | 190 | 50 | P-1 | Silicone | 1 | — | — | — | 5 | 5 | 5 |
| Exp. 3 | PET-1 | 5 | 190 | 50 | P-1 | Silicone | 3 | — | — | — | 5 | 5 | 5 |
| Exp. 4 | PET-1 | 5 | 190 | 50 | P-1 | Silicone | 10 | — | — | — | 5 | 5 | 5 |
| Exp. 5 | PET-1 | 5 | 190 | 50 | P-2 | Silicone | 5 | — | — | — | 5 | 5 | 5 |
| Exp. 6 | PET-1 | 5 | 190 | 50 | P-1 | Silicone | 3 | P-1 | Silicone | 2 | 5 | 5 | 5 |
| Exp. 7 | PET-1 | 5 | 190 | 50 | P-1 | Silicone | 3 | P-1 | Silicone | 5 | 5 | 5 | 5 |
| Exp. 8 | PET-1 | 5 | 190 | 50 | P-1 | Silicone | 3 | P-1 | Silicone | 10 | 5 | 5 | 5 |
| Exp. 9 | PET-1 | 5 | 190 | 50 | P-1 | Silicone | 3 | P-1 | Silicone | 2 | 5 | 5 | 5 |
| Exp. 10 | PET-1 | 5 | 190 | 50 | P-1 | Silicone | 3 | P-1 | Fluoro resin | 2 | 5 | 5 | 5 |
| Exp. 11 | PET-1 | 5 | 190 | 50 | P-1 | Silicone | 3 | P-1 | Fluoro resin | 5 | 5 | 5 | 5 |
| Exp. 12 | PET-1 | 5 | 190 | 50 | P-1 | Silicone | 3 | P-1 | Fluoro resin | 10 | 5 | 5 | 5 |
| Exp. 13 | PET-1 | 5 | 190 | 50 | PS-1 | Silicone | 3 | P-1 | Silicone | 5 | 5 | 5 | 5 |
| Exp. 14 | PET-1 | 5 | 190 | 50 | PS-2 | Silicone | 3 | P-1 | Silicone | 5 | 5 | 5 | 5 |
| Exp. 15 | PET-1 | 5 | 190 | 50 | PS-3 | Silicone | 3 | P-1 | Silicone | 5 | 5 | 5 | 5 |
| Comp. Exp. 1 | PET-1 | 5 | 190 | 50 | P-4 | Polyester | 5 | — | — | — | 5 | 2 | 2 |
| Comp. Exp. 2 | PET-1 | 5 | 190 | 50 | P-5 | Polyurethane | 5 | — | — | — | 5 | 2 | 2 |
| Comp. Exp. 3 | PET-2 | 5 | 225 | 7 | P-1 | Silicone | 5 | — | — | — | 5 | 2 | 5 |
| Comp. Exp. 4 | PET-1 | 5 | 190 | 50 | PS-4 | Silicone | 3 | P-1 | Silicone | 5 | 5 | 2 | 5 |

| | | | | | | | | | | | |
|---|---|---|---|---|---|---|---|---|---|---|---|
| Comp. Exp. 5 | PET-1 | 5 | 190 | 50 | PS-5 | Silicone | 3 | P-1 | Silicone | 5 | aggregation occurred |

In Table 1, the abbreviation “Exp.” denotes “Example”, the abbreviation “Comp. Exp.” denotes “Comparative Example”, the abbreviation “AERR” denotes “Average elongation retention ratio”, the abbreviation “Thick.” denotes “Thickness”, and the abbreviation “LTMH” denotes “Lapse of time under moisture and heat”.

As is understood from Table 2, all the polymer sheets of Examples exhibited excellent adhesiveness after a lapse of time under moisture and heat, as compared with the polymer sheets of Comparative Examples. Further, regarding the durability, the polymer sheets of Examples were more excellent than the polymer sheets 101 and 102 of Comparative Examples 1 and 2, which did not use the composite polymer according to the invention.

### Production of Backsheet (Backsheet for Solar Cell)

### Example 16 to Example 30

A corona treatment was performed with respect to the surface of the side of the polymer sheet 1 to polymer sheet 15 of Example 1 to Example 15 opposite from the surface (front face) at which a polymer layer is disposed, that is, the rear face surface of the support (PET-1 or PET-2). The corona treatment conditions were the same as those in the corona treatment that was performed with respect to the front face of PET-1 to PET-3. The following under coating layer and colored layer were provided on the rear face of the support that had been corona treated, to produce backsheet 1 to backsheet 15.

[Under Coating Layer]

### Preparation of Coating Liquid for Forming Under Coating Layer

The components of the following composition were mixed, and thus a coating liquid for forming an under coating layer was prepared.

(Composition of Coating Liquid)

| | |
|---|---|
| Polyester binder | 48.0 parts |
| (trade name: VYLONAL DM1245 | |
| (manufactured by Toyobo Co., Ltd.; solids | |
| content: 30% by mass)) | |
| Carbodiimide compound (crosslinking agent) | 10.0 parts |
| (trade name: CARBODILITE V-02-L2, | |
| manufactured by Nisshinbo Industries, Inc.; | |
| solids content: 10% by mass) | |
| Oxazoline compound (crosslinking agent) | 3.0 parts |
| (trade name: EPOCROS WS700, | |
| manufactured by Nippon Shokubai Co., Ltd.; | |
| solids content: 25% by mass) | |
| Surfactant | 15.0 parts |
| (trade name: NAROACTY CL95, | |
| manufactured by Sanyo Chemical Industries, | |
| Ltd.; solids content: 1% by mass) | |
| Distilled water | 907.0 parts |

—Formation of Under Coating Layer—

The coating liquid for forming an under coating layer thus obtained was applied on the rear face (rear face of the support) surface of each of polymer sheet 1 to polymer sheet 15, so that the amount of binder in terms of the amount of application was 0.1 g/m², and the coating liquid was dried for one minute at 180° C. Thus, an under coating layer having a dry thickness of about 0.1 μm was formed.

[Colored Layer]

—Preparation of Coating Liquid for Colored Layer—

Various components of the following components were mixed, and thus a coating liquid for colored layer was prepared.

(Composition of Coating Liquid)

| | |
|---|---|
| Pigment dispersion-1 | 80.0 parts |
| (same as the pigment dispersion prepared in Example 1) | |
| Silanol-modified polyvinyl alcohol binder | 11.4 parts |
| (trade name: R1130, manufactured by Kuraray Co., Ltd.; | |
| solids content: 7% by mass) | |
| Polyoxyalkylene alkyl ether | 1.0 parts |
| (trade name: NAROACTY CL95, manufactured by | |
| Sanyo Chemical Industries, Ltd.; | |
| solids content: 1% by mass) | |
| Oxazoline compound | 2.0 parts |
| (trade name: EPOCROS WS700, manufactured by | |
| Nippon Shokubai Co., Ltd.; solids | |
| content: 25% by mass, crosslinking agent) | |
| Distilled water | 5.6 parts |

—Formation of Colored Layer—

The coating liquid for colored layer thus obtained was applied on each of the rear surface of polymer sheet 1 to polymer sheet 15, on which an under coating layer has been formed, and the coating liquid was dried for one minute at 180° C. Thus, a colored layer having an amount of titanium dioxide of 7.0 g/m² and binder of 1.2 g/m² was formed.

In this way, backsheet 1 to backsheet 15 of Example 16 to Example 30 were produced. The backsheet 1 to backsheet 15 thus obtained were evaluated in a manner substantially similar to that in the polymer sheet 1 of Example 1. As a result, in all the evaluations, results fell in grade 5, and it was understood that all the backsheets exhibited excellent adhesiveness and excellent durability.

### Production of Solar Cell Module

### Example 31 to Example 45

A reinforced glass having a thickness of 3.2 mm, an EVA sheet [trade name: SC50B, manufactured by Mitsui Chemicals Fabro, Inc.], a crystalline photovoltaic cell, an EVA sheet [trade name: SC50B, manufactured by Mitsui Chemicals Fabro, Inc.], and one of the backsheet 1 to backsheet 15 of Example 16 to Example 30 were superposed in this order, and the assembly was hot pressed using a vacuum laminator [vacuum laminating machine, manufactured by Nisshinbo Industries, Inc.], to adhere the respective member and the EVA sheets. Here, the backsheet was disposed such that the colored layer of the backsheet was in contact with the EVA sheet. The condition for the adhesion to the EVA sheet was as follows.

The assembly was subjected to a vacuum at 128° C. for 3 minutes, using a vacuum laminator, and then was pressed for 2 minutes to achieve provisional adhesion. Thereafter, the resulting assembly was subjected to a main adhesion treatment in a dry oven at 150° C. for 30 minutes.

In this way, crystalline solar cell modules 1 to 15 were produced.

Using the solar cell module 1 to solar cell module 15 thus obtained, power generation operation was conducted. As a result, all the solar cell modules exhibited satisfactory power generation performance as a solar cell.

### Example 46

Polymer sheet 16 was produced in a manner substantially similar to that in Example 1, except that PET-3 was used as a support instead of using PET-1 in the production of polymer sheet 1 in Example 1. The polymer sheet 16 thus obtained, an aluminum foil (a barrier layer) having a thickness or 20 μm, a PET support (PET-4) having a thickness of 188 μm, and a white PET support (PET-5) having a thickness of 50 μm were adhered in this order, to produce backsheet 16.

Here, in the adhesion, each of the surfaces of PET-4 and PET-5 was in advance subjected to the same corona treatment as that applied to PET-1 to PET-3.

(Condition for Adhesion)

Using, as the adhesive, a mixture obtained by mixing LX 660 (K) [trade name, manufactured by DIC Corp.; adhesive] with 10 parts of a curing agent KW75 [trade name, manufactured by DIC Corp.; adhesive], the polymer sheet 16, the aluminum foil, PET-4, and PET-5 were hot press-adhered using a vacuum laminator [vacuum laminating machine, manufactured by Nisshinbo Industries, Inc.].

The assembly was subjected to a vacuum at 80° C. for 3 minutes, and then was pressed for 2 minutes to achieve adhesion. Thereafter, the resulting assembly was maintained at 40° C. for 4 days.

Solar cell module 16 was produced in a manner substantially similar to that in the production of solar cell module 1 in Example 31, except that backsheet 16 thus obtained was used instead of using backsheet 1.

Using the solar cell module 16 thus produced, power generation operation was conducted. As a result, the solar cell module exhibited satisfactory power generation performance as a solar cell.

### Example 47

Backsheet 17 was produced in a manner substantially similar to that in the production of backsheet 16 in Example 46, except that a barrier layer-attached PET sheet having a thickness of 12 μm was used instead of using the aluminum foil.

Further, solar cell module 17 was produced in a manner substantially similar to that in the production of solar cell module 16 in Example 46, except backsheet 17 was used instead of using backsheet 16.

Using the solar cell module 17 thus produced, power generation operation was conducted. As a result, the solar cell module exhibited satisfactory power generation performance as a solar cell.

The foregoing description of the exemplary embodiments of the present invention has been provided for the purposes of illustration and description. It is not intended to be exhaustive or to limit the invention to the precise forms disclosed. The embodiments were chosen and described in order to best explain the principles of the invention and its practical applications, thereby enabling others skilled in the art to understand the invention for various embodiments and with the various modifications as are suited to the particular use contemplated.

This application claims priority from Japanese Patent Application No. 2011-068658 filed on Mar. 25, 2011, the disclosure of which is incorporated by reference herein. All publications, patent applications, and technical standards mentioned in this specification are herein incorporated by reference to the same extent as if such individual publication, patent application, or technical standard was specifically and individually indicated to be incorporated by reference. It will be obvious to those having skill in the art that many changes may be made in the above-described details of the preferred embodiments of the present invention. It is intended that the scope of the invention be defined by the following claims and their equivalents.

What is claimed is:

1. A polymer sheet for a solar cell, the polymer sheet comprising:
a polyester base material which has a carboxyl group content of 15 eq/t or less, a minute endothermic peak temperature Tmeta (° C.) of 220° C. or lower as determined by differential scanning calorimetry, and an average elongation retention ratio of 10% or more as determined after being allowed to stand under the conditions of a temperature of 125° C. and a relative humidity of 100% RH for 72 hours; and
a polymer layer which is provided on the polyester base material and comprises a composite polymer which contains, in a molecule, 15% by mass to 85% by mass of siloxane structural units represented by the following Formula (1) and 85% by mass to 15% by mass of non-siloxane-based structural units: 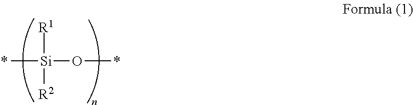
wherein, in Formula (1), each of R¹ and R² independently represents a hydrogen atom, a halogen atom or a monovalent organic group; R¹ and R² may be same or different from each other; a plurality of R¹ and R² may be same or different from each other; and n represents an integer of 1 or more.

2. The polymer sheet for a solar cell according to claim 1, wherein the polymer layer comprises a structural unit derived from a crosslinking agent that crosslinks the composite polymer.

3. The polymer sheet for a solar cell according to claim 1, wherein the non-siloxane-based structural unit comprises an acrylic structural unit.

4. The polymer sheet for a solar cell according to claim 2, wherein the crosslinking agent is at least one selected from the group consisting of a carbodiimide compound, an oxazoline compound and an epoxide-based crosslinking agent.

5. The polymer sheet for a solar cell according to claim 2, wherein a mass ratio of a portion of the structural unit derived from the crosslinking agent is in a range of from 1% by mass to 30% by mass with respect to a mass of the composite polymer in the polymer layer.

6. The polymer sheet for a solar cell according to claim 1, wherein the polyester base material is treated by at least one surface treatment selected from the group consisting of corona treatment, flame treatment, low-pressure plasma treatment, atmospheric pressure plasma treatment and ultraviolet ray treatment.

7. The polymer sheet for a solar cell according to claim 1, wherein, in Formula (1), at least one of R¹ or R² represents a monovalent organic group selected from the group consisting of an alkyl group, an aryl group, an aralkyl group, an alkoxy group, an aryloxy group, a mercapto group, an amino group and an amido group.

8. The polymer sheet for a solar cell according to claim 1, wherein a content of a carboxyl group in the polyester base material is in a range of from 1 eq/ton to 15 eq/ton.

9. The polymer sheet for a solar cell according to claim 1, wherein the polymer sheet comprises at least two layers of the polymer layers, and a thickness of at least one layer of the polymer layers is in a range of from 0.8 μm to 12 μm.

10. The polymer sheet for a solar cell according to claim 1, wherein the polymer sheet comprises at least two layers of the polymer layers, and at least one layer of the polymer layers is provided in contact with a surface of the polyester base material.

11. The polymer sheet for a solar cell according to claim 1, wherein the polymer sheet comprises at least two layers of the polymer layers, and at least one layer of the polymer layers is an outermost layer provided at a furthest position from a surface of the polyester base material.

12. The polymer sheet for a solar cell according to claim 1, wherein the polymer sheet comprises at least two layers of the polymer layers, and at least one layer of the polymer layers further comprises a white pigment and is a reflective layer having light reflective properties.

13. The polymer sheet for a solar cell according to claim 12, wherein the polymer sheet comprises at least two layers of the polymer layers, one of the at least two layers is the reflective layer, and another of the at least two layers is provided between the reflective layer and the polyester base material.

14. The polymer sheet for a solar cell according to claim 1, further comprising a reflective layer that comprises a white pigment and has light reflective properties, and comprising at least one layer of the polymer layers between the reflective layer and the polyester base material.

15. A method of producing a polymer sheet for a solar cell, the method comprising: applying, on a polyester base material, a coating liquid containing a composite polymer which contains, in a molecule, 15% by mass to 85% by mass of siloxane structural units represented by the following Formula (1) and 85% by mass to 15% by mass of non-siloxane-based structural units to form at least one polymer layer, the polyester base material having a carboxyl group content of 15 eq/t or less, a minute endothermic peak temperature Tmeta (° C.) of 220° C. or lower as determined by differential scanning calorimetry, and an average elongation retention ratio of 10% or more as determined after being allowed to stand under the conditions of a temperature of 125° C. and a relative humidity of 100% RH for 72 hours: 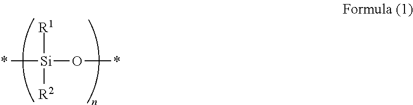
wherein, in Formula (1), each of R¹ and R² independently represents a hydrogen atom, a halogen atom or a monovalent organic group; R¹ and R² may be same or different; a plurality of R¹ and R² may be same or different; and n represents an integer of 1 or more.

16. The method of producing a polymer sheet for a solar cell according to claim 15, wherein the coating liquid further comprises at least one crosslinking agent selected from the group consisting of a carbodiimide compound, an oxazoline compound and an epoxide-based crosslinking agent.

17. The method of producing a polymer sheet for a solar cell according to claim 15, wherein the coating liquid further comprises a solvent, and 50% by mass or greater of the solvent is water.

18. A backsheet for a solar cell using the polymer sheet for a solar cell according to claim 1, the backsheet being provided in contact with a sealing agent, wherein a solar cell element is sealed by the sealing agent on a side of a base material for the solar cell element.

19. The backsheet for a solar cell according to claim 18, further comprising a readily-adhesive layer having an adhesion force of 5N/cm or greater with respect to the sealing agent on an opposite surface side of the polyester base material from a surface side at which the polymer layer is provided.

20. The backsheet for a solar cell according to claim 18, comprising two or more polymer sheets which are the polymer sheets for a solar cell, the two or more polymer sheets being adhered together with an adhesive agent.

21. The backsheet for a solar cell according to claim 18, further comprising a barrier layer which prevents penetration of at least one of water or gas therein.

22. A solar cell module comprising the backsheet for a solar cell according to claim 18.

23. A solar cell module comprising:
a transparent front base board through which sunlight enters;
a cell structural portion which is provided on the front base board and comprises a solar cell element and a sealing material that seals the solar cell element; and
the backsheet for a solar cell according to claim 18, the backsheet being provided on a side of the cell structural portion opposite from a side at which the front base board is placed, so as to be adjacent to the sealing material.

24. The polymer sheet for a solar cell according to claim 4, wherein the non-siloxane-based structural unit comprises an acrylic structural unit, and a mass ratio of a portion of the structural unit derived from the crosslinking agent is in a range of from 1% by mass to 30% by mass with respect to a mass of the composite polymer in the polymer layer.

25. The polymer sheet for a solar cell according to claim 24, wherein the polyester base material is treated by at least one surface treatment selected from the group consisting of corona treatment, flame treatment, low-pressure plasma treatment, atmospheric pressure plasma treatment and ultraviolet ray treatment.

26. The polymer sheet for a solar cell according to claim 24, wherein, in Formula (1), the monovalent organic group represented by R¹ and R² is independently a group selected from the group consisting of an alkyl group, an aryl group, an aralkyl group, an alkoxy group, an aryloxy group, a mercapto group, an amino group and an amido group.

27. The polymer sheet for a solar cell according to claim 24, wherein the polymer sheet comprises at least two layers of the polymer layers, at least one layer of the polymer layers further comprises a white pigment and is a reflective layer having light reflective properties, one of the at least two layers being the reflective layer, and another of the at least two layers being provided between the reflective layer and the polyester base material.
